(19) United States
(12) Patent Application Publication
(10) Pub. No.: US 2014/0113403 A1
(43) Pub. Date: Apr. 24, 2014

(54) High efficiency CZTSe by a two-step approach

(71) Applicant: INTERMOLECULAR INC., San Jose, CA (US)

(72) Inventors: Jeroen Van Duren, Palo Alto, CA (US); Ben Cardozo, San Jose, CA (US); Haifan Liang, Fremont, CA (US)

(73) Assignee: INTERMOLECULAR INC., San Jose, CA (US)

(21) Appl. No.: 14/139,309

(22) Filed: Dec. 23, 2013

Related U.S. Application Data
(63) Continuation-in-part of application No. 13/595,888, filed on Aug. 27, 2012.

(51) Int. Cl. H01L 31/18

(52) U.S. Cl. CPC H01L 31/1864
USPC 438/95

(57) ABSTRACT

Methods of forming CZTS absorber layers in a TFPV device with a graded bandgap with or without a graded concentration are provided. In general, a Cu—Zn—Sn—(S, Se) precursor film is formed by sputtering. The Cu—Zn—Sn—(S, Se) precursor film can be formed as a single layer or as a multilayer stack. The composition may be uniform or graded throughout the thickness of the film. In some embodiments, the sputtering is performed in a reactive atmosphere including a chalcogen source (e.g. H₂S, H₂Se, etc.). The films, in conjunction with a subsequent selenization or anneal process, are converted to an absorber layer.

### CROSS-REFERENCE TO RELATED APPLICATIONS

This application is a Continuation-in-Part of U.S. patent application Ser. No. 13/595,888 filed on Aug. 27, 2012, which further claims priority to U.S. Provisional Patent Application Ser. No. 61/578,691 filed on Dec. 21, 2011, each of which are herein incorporated by reference for all purposes.

### FIELD OF THE DISCLOSURE

This disclosure relates to thin film photovoltaic devices, and more particularly, to an absorber layer for a thin film photovoltaic device that has a graded bandgap, and methods of forming the same. More specifically, methods of developing absorbers for copper zinc tin (sulfide) selenide (CZT(S)Se, or CZTS) solar cells are discussed.

### BACKGROUND OF THE DISCLOSURE

Solar cells are photovoltaic (PV) devices that convert light into electrical energy. Solar cells have been developed as clean, renewable energy sources to meet growing demand. Solar cells have been implemented in a wide number of commercial markets including residential rooftops, commercial rooftops, utility-scale PV projects, building integrated PV (BIPV), building applied PV (BAPV), PV in electronic devices, PV in clothing, etc. Currently, crystalline silicon solar cells (both mono-crystalline and multi-crystalline) are the dominant technologies in the market. Crystalline silicon (cSi) solar cells must use a thick substrate (>100 um) of silicon to absorb the sunlight since it has an indirect bandgap and low absorption coefficient. The use of a thick substrate also means that the crystalline silicon solar cells must use high quality material to provide long carrier lifetimes. Therefore, crystalline silicon solar cell technologies lead to increased costs. Thin film photovoltaic (TFPV) solar devices based on amorphous silicon (a-Si), CIGS, cadmium telluride (CdTe), copper zinc tin sulfide (CZTS), etc. provide an opportunity to increase the material utilization since only thin films (<10 um) are generally required. The thin film solar cells may be formed from amorphous, nanocrystalline, micromorph, micro-crystalline, polycrystalline, or mono-crystalline materials. TFPV devices may include a single absorber layer for converting light into electricity, or multiple absorber layers with tuned absorption spectra for converting light into electricity in a tandem configuration. The tandem configuration might be a two-terminal device, or a multi-terminal (e.g. four-terminal) device structure. The multi-terminal device structure might be comprised of one stack of layers on one substrate, or involve different stacks of layers on multiple stacked substrates.

TFPV devices provide an opportunity to reduce energy payback time, and reduce water usage for solar panel manufacturing. Typical CdTe and CZTS films have bandgaps of about 1.5 eV and therefore, are an ideal match for the AM1.5G solar spectrum to allow for high efficiencies. The absorption coefficient for CdTe is about 10⁵/cm and the absorption coefficient for CZTS is about 10⁴/cm. CIGS films have bandgaps in the range of 1.0 eV (CIS) to 1.65 eV (CGS) and are also efficient absorbers across the entire solar spectrum. The absorption coefficient for CIGS is also about 10⁵/cm. Among the thin film solar technologies, CIGS has demonstrated the best lab cell efficiency (over 20%) and the best large area module efficiency (>15%).

Two general classes of PV absorber films of special interest are formed as CIGS-type IB-IIIA-VIA multinary chalcogenide compounds from Groups IB, IIIA, and VIA of the periodic table or as CZTS-type multinary compounds from Groups IB-IIB-IVA-VIA of the periodic table. Group IB includes Cu, Ag, and Au. Group IIIA includes B, Al, Ga, In, and TI. Group VIA includes O, S, Se, Te, and Po. Additionally, the IB-IIIA-VIA materials can be doped with dopants from Groups VIII, IIB, IVA, VA, and VIIA of the periodic table. Group VIII includes Fe, Ru, Os, Co, Rh, Ir, Ni, Pd, and Pt. Group IIB includes Zn, Cd, and Hg. Group IVA includes C, Si, Ge, Sn, and Pb. Group VA includes N, P, As, Sb, and Bi. Group VIIA includes F, Cl, Br, I, and At. Other potential absorber materials of interest include kesterites like CZTS, cuprous oxide, iron sulfide, tungsten sulfide, calcium nitride, zinc phosphide, barium silicide, etc.

TFPV devices can be fabricated at the cell level or the panel level, thus further decreasing the manufacturing costs. As used herein, the cell level is understood to mean an individual unit that can be combined with other units to form a module. The cells may be rigid or flexible. As used herein, the panel level is understood to mean a large TFPV structure that is not composed of smaller units. Generally, the panels are similar in size to the aforementioned modules. For economy of language, the phrase “TFPV device” will be understood to refer to either a solar cell or a panel without distinction. Furthermore, TFPV devices may be fabricated on inexpensive substrates such as glass, plastics, and thin sheets of metal. Examples of suitable substrates comprise float glass, low-iron glass, borosilicate glass, flexible glass, flexible ceramics, specialty glass for high temperature processing, stainless steel, carbon steel, aluminum, cladded foils, copper, polyimide, plastics, etc. Furthermore, the substrates may be processed in many configurations such as single substrate processing, multiple substrate batch processing, in-line continuous processing, roll-to-roll processing, etc.

The increasing demand for environmentally friendly, sustainable and renewable energy sources is driving the development of large area, thin film photovoltaic devices. With a long-term goal of providing a significant percentage of global energy demand, there is a concomitant need for Earth-abundant, high conversion efficiency materials for use in photovoltaic devices. A number of Earth abundant, direct-bandgap semiconductor materials now seem to show evidence of the potential for both high efficiency and low cost in Very Large Scale (VLS) production (e.g. greater than 100 gigawatt (GW)), yet their development and characterization remains difficult because of the complexity of the materials systems involved.

Among the TFPV technologies, CIGS and CdTe are the two that have reached volume production with greater than 11% stabilized module efficiencies. However, the supply of In, Ga and Te may impact annual production of CIGS and CdTe solar panels. Moreover, price increases and supply constraints in Ga and In could result from the aggregate demand for these materials used in flat panel displays (FPD) and light-emitting diodes (LED) along with CIGS TFPV. Also, there are concerns about the toxicity of Cd throughout the lifecycle of the CdTe TFPV solar modules. Efforts to develop devices that leverage manufacturing and R&D infrastructure related to these TFPV technologies but using more widely available and more environmentally friendly materials should be considered a top priority for research. The knowledge and infrastructure developed around CdTe and CIGS TFPV technologies can be leveraged to allow faster adoption of new TFPV materials systems.

The development of TFPV devices exploiting Earth abundant materials represents a daunting challenge in terms of the time-to-commercialization. That same development also suggests an enticing opportunity for breakthrough discoveries. A quaternary system such as CIGS requires management of multiple kinetic pathways, thermodynamic phase equilibrium considerations, defect chemistries, and interfacial control. The vast phase-space to be managed includes process parameters, source material choices, compositions, and overall integration schemes. The complexity of the intrinsically-doped, self-compensating, multinary, polycrystalline, queue-time-sensitive, thin-film absorber (CIGS), and its interfaces to up-, and down-stream processing, combined with the lack of knowledge on a device level to address efficiency losses effectively, makes it a highly empirical material system. The performance of any thin-film, (opto-)electronically-active device is extremely sensitive to its interfaces. Interface engineering for electronically-active devices is highly empirical. Traditional R&D methods are ill-equipped to address such complexity, and the traditionally slow pace of R&D could limit any new material from reaching industrial relevance when having to compete with the incrementally improving performance of already established TFPV fabrication lines, and continuously decreasing panel prices for more traditional cSi PV technologies.

Due to the complexity of the material, cell structure, and manufacturing process, both the fundamental scientific understanding and large scale manufacturability are yet to be realized for TFPV devices. As the photovoltaic industry pushes to achieve grid parity, much faster and broader investigation is needed to explore the material, device, and process windows for higher efficiency and a lower cost of manufacturing process. Efficient methods for forming different types of TFPV devices that can be evaluated are necessary.

In light of the above, there is a need in the art for an economical method of creating CZTS absorber layers having a graded bandgap. A graded bandgap allows for higher efficiency CZTS solar cells.

### SUMMARY OF THE DISCLOSURE

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, methods of forming CZTS absorber layers in a TFPV device with a graded bandgap in the absorber layer are provided. In general, a Cu—Zn—Sn—(S, Se) precursor film is formed by sputtering. The Cu—Zn—Sn—(S, Se) precursor film can be formed as a single layer or as a multilayer stack. The composition may be uniform or graded throughout the thickness of the film. In some embodiments, the sputtering is performed in a reactive atmosphere including a chalcogen containing gas (e.g. H₂S, H₂Se, etc.). The films, in conjunction with a subsequent selenization or anneal process, are converted to an absorber layer.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 illustrates a schematic diagram of a simple substrate TFPV stack according to an embodiment described herein.

FIG. 4 illustrates a schematic diagram of a simple n-superstrate TFPV stack according to an embodiment described herein.

FIG. 5 illustrates a schematic diagram of a simple p-superstrate TFPV stack according to an embodiment described herein.

FIG. 6 illustrates an absorber layer having a flat Ga profile and a flat bandgap profile.

FIG. 7 illustrates an absorber layer having a single graded Ga profile and a single graded bandgap profile.

FIG. 8 illustrates an absorber layer having a single graded Ga profile, a double graded S profile, and a double graded bandgap profile.

FIG. 9 illustrates an absorber layer having a double graded Ga profile and a double graded bandgap profile.

FIG. 10 provides a flow chart for a generic 2-step process.

FIG. 11 provides a flow chart for a generic 4-step process.

FIG. 12 is a schematic cross-sectional view of a thin film photovoltaic device with a copper-indium-gallium-selenide (CIGS) absorber layer, configured according to embodiments of the invention.

FIG. 13 sets forth a flowchart of method steps in a process sequence for forming a CIGS absorber layer, according to embodiments of the invention.

FIGS. 14A-14C sequentially illustrate cross-sectional views of a TFPV device during the execution of the process sequence illustrated in FIG. 13, according to embodiments of the invention.

FIG. 15 sets forth a flowchart of method steps in a process sequence for forming a CIGS absorber layer, according to embodiments of the invention.

FIGS. 16A-16D sequentially illustrate cross-sectional views of a TFPV device during the execution of the process sequence illustrated in FIG. 15, according to embodiments of the invention.

FIG. 17 sets forth a flowchart of method steps in a process sequence 1700 for forming a CIGS absorber layer, according to embodiments of the invention.

FIGS. 18A-18D sequentially illustrate cross-sectional views of a TFPV device during the execution of the process sequence illustrated in FIG. 17, according to embodiments of the invention.

FIG. 19 sets forth a flowchart of method steps in a process sequence for forming a CZTS absorber layer, according to embodiments of the invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%. Where the modifier “substantially equal to” or “substantially the same” is used, the two quantities may vary from each other by no more than 5%.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

As used herein, “CIGS” will be understood to represent the entire range of related alloys denoted by Cu_{z}In₍₁₋ₓ₎GaₓS_{(2+w)(1-y)}Se_{(2+w)y}, where 0.5≦z≦1.5, 0≦x≦1, 0≦y≦1, −0.2≦w≦0.5. Similarly, as noted above, other materials (i.e. Ag, Au, Te, etc.) may be incorporated into potential absorber layers, (with e.g. Ag replacing part or all of the Cu, and Te replacing part or all of the Se and/or S). Also as mentioned previously, any of these materials may be further doped with a suitable dopant. As used herein, “CIGSSe”, “CIGSe”, and “CIGS” will be defined as equivalent and will be used interchangeably and will include all compositions including Cu—In—Ga—Se—S, Cu—In—Ga—Se, and Cu—In—Ga—S. Furthermore, “CIGS” also includes other IB-IIIA-VIA alloys, like (Ag, Cu)(In, Ga)(Se), or (Cu)(In, Ga)(S, Se, Te), and the like.

As used herein, “CZTS” will be understood to represent the entire range of related alloys denoted by Cu_{z}Zn_{w}Snₓ(S_{y}Se_{1-y})₄ where 0≦y≦1 and w, x, and z range from 0 to 2. Similarly, as noted above, other materials (i.e. Ag, Au, Cd, Ge, Te, etc.) may be incorporated into potential absorber layers, (with e.g. Ag replacing part or all of the Cu, and Te replacing part or all of the Se and/or S). Also as mentioned previously, any of these materials may be further doped with a suitable dopant. As used herein, “CZTSSe”, “CZTSe”, and “CZTS” will be defined as equivalent and will be used interchangeably and will include all compositions including Cu—Zn—Sn—Se—S, Cu—Zn—Sn—Se, and Cu—Zn—Sn—S. Furthermore, “CZTS” also includes other IB-IIB-IVA-VIA alloys, like (Ag, Cu)(Zn, Cd)(Sn, Ge)(Se, S), and the like.

As used herein, the notation “(IIIA)” will be understood to represent the sum of the concentrations of all Group-IIIA elements. This notation will be used herein in calculations of the composition ratios of various elements. This notation will be understood to extend to each of the other Groups of the periodic table respectively (e.g. “(IA)”, “(IIA)”, “(IVA)”, “(VIA)”, “(IB)”, “(IIB)”, etc.).

As used herein, the notation “Cu—In—Ga” and “Cu(In, Ga)” will be understood to include a material containing these elements in any ratio. The notation is extendable to other materials and other elemental combinations.

As used herein, the notation “Cu—Zn—Sn” and “Cu(Zn, Sn)” will be understood to include a material containing these elements in any ratio. The notation is extendable to other materials and other elemental combinations.

As used herein, the notation “CuₓIn_{y}Ga_{z}” will be understood to include a material containing these elements in a specific ratio given by x, y, and z (e.g. Cu₇₅Ga₂₅ contains 75 atomic % Cu and 25 atomic % Ga). The notation is extendable to other materials and other elemental combinations.

As used herein, the notation “CuₓZn_{y}Sn_{z}” will be understood to include a material containing these elements in a specific ratio given by x, y, and z (e.g. Cu₇₅Sn₂₅ contains 75 atomic % Cu and 25 atomic % Sn). The notation is extendable to other materials and other elemental combinations.

As used herein, the notation “(Ag, Cu)ₓ(In, Ga)_{y}(Se, S, Te)_{z}” will be understood to include a material containing a total amount of Group-IB elements (i.e. Ag plus Cu, etc.) in a ratio given by “x”, a total amount of Group-IIIA elements (i.e. In plus Ga), etc. in a ratio given by “y”, and a total amount of Group-VIA elements (i.e. Se plus S plus Te, etc.) in a ratio given by “z”. The notation is extendable to other materials and other elemental combinations.

As used herein, “metal chalcogenide” or “chalcogenide” will be understood to represent the entire range of related compounds denoted by “MX” where M represents one or more metal elements and X represents one or more of the chalcogen elements (e.g. O, S, Se, or Te).

As used herein, “chalcogenize” and “chalcogenization” will be understood to represent the process by which one or more metals are converted to chalcogenide compounds by exposing the one or more metals to a chalcogen (e.g. O, S, Se, or Te) at elevated temperature (e.g. between 100 C and 700 C). Specifically, “selenization” will be understood to represent the process by which one or more metals are converted to selenide compounds by exposing the one or more metals to a Se source at elevated temperature (e.g. between 100 C and 700 C). Specifically, “sulfurization” will be understood to represent the process by which one or more metals are converted to sulfide compounds by exposing the one or more metals to a S source at elevated temperature (e.g. between 100 C and 700 C). In addition, “chalcogenize” or “chalcogenization” will be understood to represent the process by which a metal precursor is either partially or completely converted to the final multinary chalcogenide compound(s). Similarly, “chalcogenize” or “chalcogenization” will be understood to represent the process by which a precursor containing one or more chalcogenide materials with/without one or more elemental or alloy metals is converted to one or more dense, polycrystalline, desired multinary chalcogenide compound(s). It should be understood that the majority of the final film contains the desired multinary chalcogenide compound(s), yet a minority of the material might not be converted to the desired multinary chalcogenide compound(s).

As used herein, the terms “film” and “layer” will be understood to represent a portion of a stack. They will be understood to cover both a single layer as well as a multilayered structure (i.e. a nanolaminate). As used herein, these terms will be used synonymously and will be considered equivalent.

As used herein, “single grading” and “single gradient” will be understood to describe cases wherein a parameter varies throughout the thickness of a film or layer and further exhibits a smooth, quasilinear variation. Examples of suitable parameters used herein will include the atomic concentration of a specific elemental species (i.e. composition variation) throughout the thickness of a film or layer, and bandgap energy variation throughout the thickness of a film or layer.

As used herein, “double grading” and “double gradient” will be understood to describe cases wherein a parameter varies throughout the thickness of a film or layer and further exhibits a variation wherein the value of the parameter is smaller toward the middle of the film or layer with respect to either end of the film or layer. It is not a requirement that the value of the parameter be equivalent at the two ends of the film or layer. Examples of suitable parameters used herein will include the atomic concentration of a specific elemental species (i.e. composition variation) throughout the thickness of a film or layer, and bandgap energy variation throughout the thickness of a film or layer.

As used herein, “substrate configuration” will be understood to describe cases wherein the TFPV stack is built sequentially on top of a substrate and the light is assumed to be incident upon the top of the TFPV stack. As used herein, an “n-substrate” configuration will be used to denote that the n-type layer (i.e. buffer layer) is closest to the incident light. The n-substrate configuration is the most common. As used herein, a “p-substrate” configuration will be used to denote that the p-type layer (i.e. absorber layer) is closest to the incident light.

As used herein, “superstrate configuration” will be understood to describe cases wherein the substrate faces the incident sunlight. The convention will be used wherein light is assumed to be incident upon the substrate. As used herein, a “n-superstrate” configuration will be used to denote that the n-type layer (i.e. buffer layer) is closest to the incident light. As used herein, a “p-superstrate” configuration will be used to denote that the p-type layer (i.e. absorber layer) is closest to the incident light.

As used herein, “substrate” will be understood to generally be one of float glass, low-iron glass, borosilicate glass, flexible glass, specialty glass for high temperature processing, stainless steel, carbon steel, aluminum, copper, titanium, molybdenum, polyimide, plastics, cladded metal foils, etc. Furthermore, the substrates may be processed in many configurations such as single substrate processing, multiple substrate batch processing, in-line continuous processing, roll-to-roll processing, etc. in all of the methods and examples described herein.

As used herein, “precursor layer”, “precursor material”, “metal precursor layer”, “metal precursor material”, etc. will be understood to be equivalent and be understood to refer to a metal, metal alloy, metal chalcogenide, etc. layer and/or material that is first deposited and will ultimately become the absorber layer of the TFPV device after full chalcogenization and/or further processing.

As used herein, “absorber layer”, “absorber material”, etc. will be understood to be equivalent and be understood to refer to a layer and/or material that is responsible for the charge generation in the TFPV device after full chalcogenization and/or further processing.

As used herein, the notations “Al:ZnO” and “ZnO:Al” will be understood to be equivalent and will describe a material wherein the base material is the metal oxide and the element separated by the colon “:” is considered a dopant. In this example, Al in a dopant in a base material of zinc oxide. The notation is extendable to other materials and other elemental combinations.

As used herein, a “bandgap-increasing metal” will be understood to be a metal element that increases the bandgap when substituted for an element from the same periodic table Group in the absorber material. For example, substituting Ag for a portion of the Cu in a CIGS material will increase the bandgap. For example, increasing the relative amount of Ga versus indium in a CIGS material will increase the bandgap. For example, substituting Ag for a portion of the Cu in a CZTS material will increase the bandgap. For example, substituting Ge for a portion of the Sn in a CZTS material will increase the bandgap.

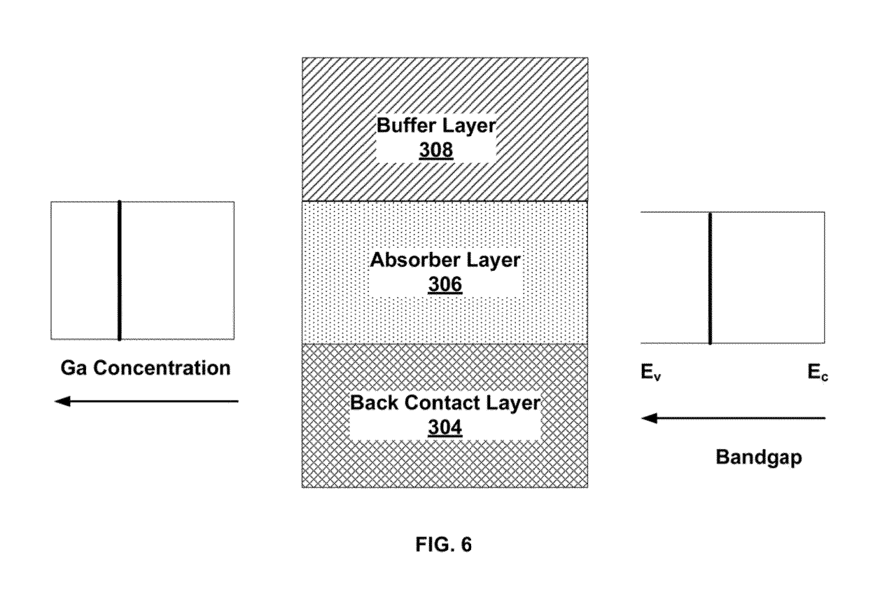

The bandgap value represents the energy difference between the top of the valence band and the bottom of the conduction band in the CIGS absorber layer. In FIGS. 6-9, 12, 14, 16, and 18, the bandgap diagrams are included to aid the reader in visualizing the relative magnitude of the bandgap across the absorber layer. No inferences should be made with respect to absolute values or actual changes in either the valance band or conduction band values. The diagrams are for visualization purposes only.

In various FIGs. below, a TFPV material stack is illustrated using a simple planar structure. Those skilled in the art will appreciate that the description and teachings to follow can be readily applied to any simple or complex TFPV solar cell structure, (e.g. a stack with (non-)conformal non-planar layers for optimized photon management). The drawings are for illustrative purposes only and do not limit the application of the present invention.

“Double grading” the bandgap of the CIGS absorber is a method known in the art to increase the efficiency of CIGS solar cells. In a CIGS absorber layer that has a double-graded bandgap profile, the bandgap of the CIGS layer increases toward the front surface and toward the back surface of the CIGS layer, with a bandgap minimum located in a center region of the CIGS layer. Double grading helps in reducing unwanted charge carrier recombination. The increasing bandgap profile at the back surface of the CIGS layer, (i.e., the absorber surface that is remote from the incident light in the substrate configuration), creates a back surface field, which reduces recombination at the back surface and enhances carrier collection. Generally, in the disclosure to follow, the description will applied to the “n-substrate” configuration for economy of language. However, those skilled in the art will understand that the disclosure is equally applicable to either of the “p-substrate” or “n, p-superstrate” configurations discussed previously and the disclosure will not be limited to only the “substrate configuration”.

Co-evaporation is one technique known in the art for producing a double-graded bandgap in a CIGS absorber layer. The co-evaporation process can produce a “gallium (Ga) rich region” (i.e. increased Ga relative to the center region of the layer) at the front and/or back surfaces of a CIGS absorber layer and a gallium-poor region in the center of the CIGS absorber layer. However, co-evaporation is a relatively complex process that is not as economical or as easily implemented as other deposition processes known in the art. In a 2-step process, Cu—In—Ga metal precursors are deposited first, followed by a second selenization process to form a CIGS absorber layer. The 2-step process is generally more suited to large-scale low-cost manufacturing compared to the co-evaporation process. However, because gallium selenizes slower than indium under otherwise identical conditions, gallium tends to accumulate towards the back surface of the CIGS layer during the selenization process, thereby creating an uncontrolled single grading in the bandgap profile, i.e., the bandgap of the CIGS layer increases from the front surface to the back surface. Double grading of the bandgap profile is then typically achieved by the incorporation of sulfur (S) at the front surface of the CIGS layer for a 2-step process thereby creating CIGSSe. However, sulfur incorporation adds considerable complexity to the growth process and more easily produces a TFPV absorber material (copper-indium-gallium-selenium-sulfur) of lower quality compared to CIGSe without sulfur.

The efficiency of TFPV devices depends on many properties of the absorber layer and the buffer layer such as crystallinity, grain size, composition uniformity, density, defect concentration, doping level, surface roughness, etc.

The manufacture of TFPV devices entails the integration and sequencing of many unit processing steps. As an example, TFPV manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as TFPV devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, the entireties of which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005, the entireties of which are all herein incorporated by reference.

HPC processing techniques have been successfully adapted to wet chemical processing such as etching, texturing, polishing, cleaning, etc. HPC processing techniques have also been successfully adapted to deposition processes such as sputtering, atomic layer deposition (ALD), and chemical vapor deposition (CVD).

HPC processing techniques have been adapted to the development and investigation of absorber layers and buffer layers for TFPV solar cells as described in U.S. application Ser. No. 13/236,430 filed on Sep. 19, 2011, entitled and is incorporated herein by reference for all purposes. However, HPC processing techniques have not been successfully adapted to the development of contact structures for TFPV devices. Generally, there are two basic configurations for TFPV devices. The first configuration is known as a “substrate” configuration. In this configuration, the contact that is formed on or near the substrate is called the back contact. In this configuration, the light is incident on the TFPV device from the top of the material stack (i.e. the side opposite the substrate). CIGS and CZTS TFPV devices are most commonly manufactured in this configuration. The second configuration is known as a “superstrate” configuration. In this configuration, the contact that is formed on or near the substrate is called the front contact. In this configuration, the light is incident on the TFPV device through the substrate. CdTe, and a-Si, TFPV devices are most commonly manufactured in this configuration. In both configurations, light trapping schemes may be implemented in the contact layer that is formed on or near the substrate. Additionally, other efficiency or durability improvements can be implemented in the contact layer that is formed farthest away from the substrate.

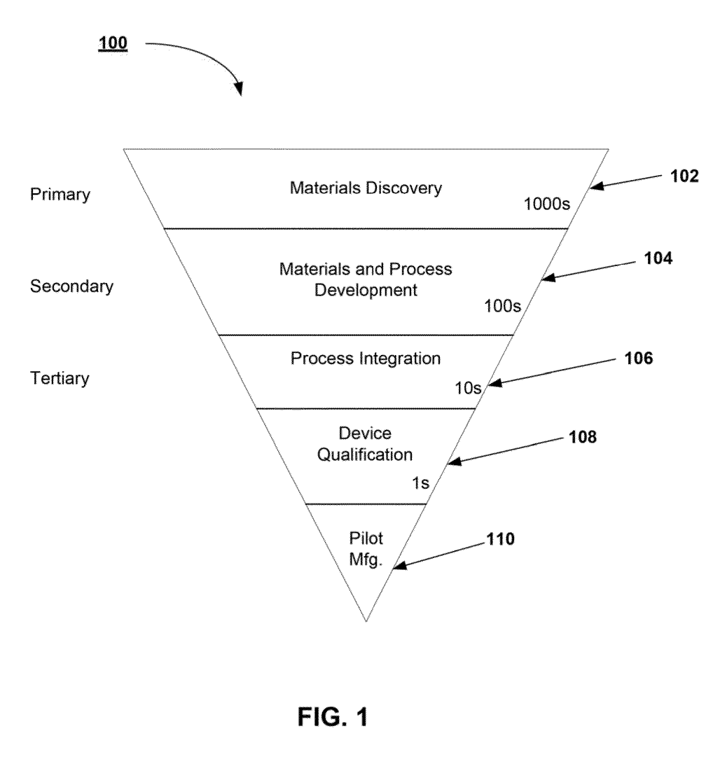

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of TFPV manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a TFPV device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a TFPV device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the TFPV device. For example, such structures may include, but would not be limited to, contact layers, buffer layers, absorber layers, or any other series of layers or unit processes that create an intermediate structure found on TFPV devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

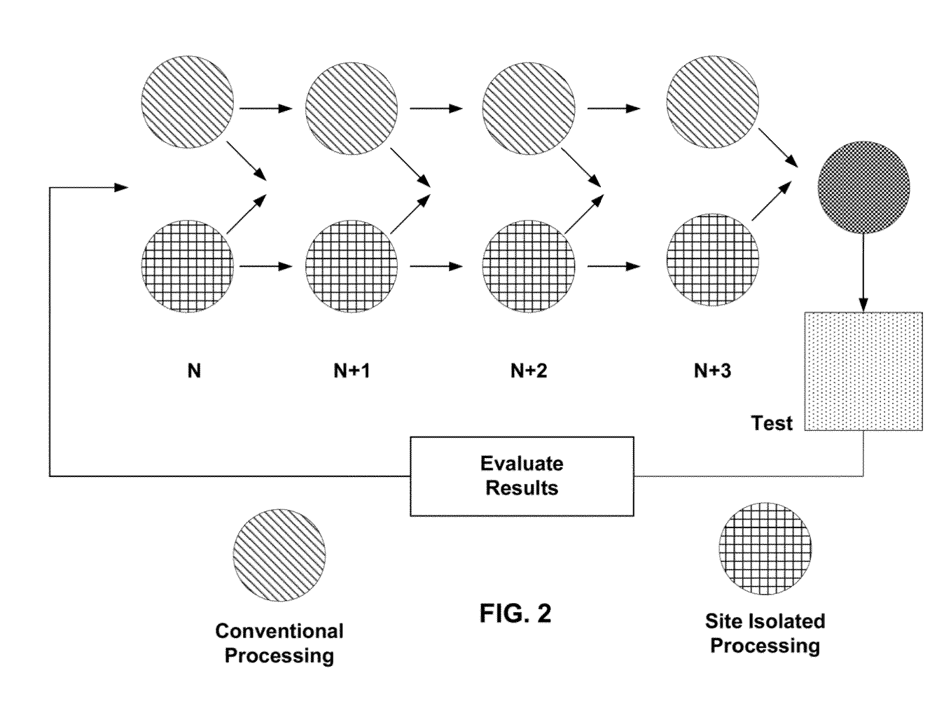

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. The combinatorial processing may employ uniform processing of site isolated regions or may employ gradient techniques. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

As mentioned above, within a region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the regions. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Absorber layers based on CIGS have been used extensively in the development and manufacture of TFPV devices. Therefore, the materials used for the various layers within the TFPV stack and the processes used for their formation have been studied extensively. TFPV devices based on CZTS absorbers have generally adopted the same materials and processes used for CIGS based TFPV devices. However, these materials and processes may not be appropriate for CZTS based TFPV devices to form devices with high efficiency. Therefore, the HPC techniques discussed previously can be applied to the development of TFPV stacks based on CZTS absorber layers to improve their efficiencies. The following discussion will use generic CIGS based TFPV stacks to discuss the position and function of the various layers. Where appropriate, a discussion will be added where HPC techniques might be employed in the development of CZTS based TFPV stacks.

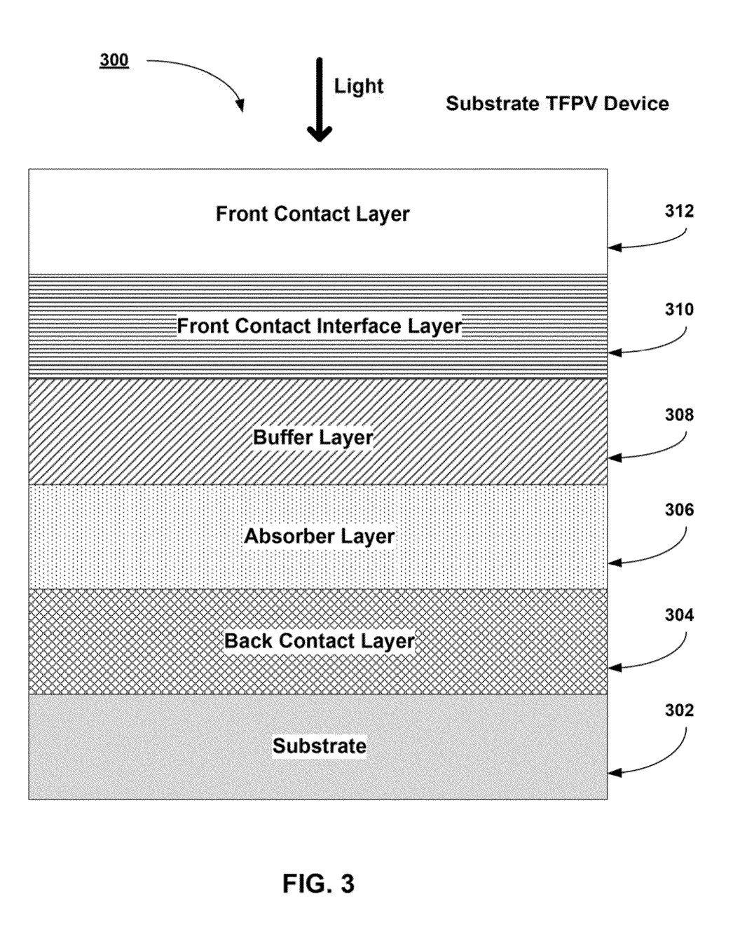

FIG. 3 illustrates a schematic diagram of a simple TFPV device stack in the substrate configuration consistent with some embodiments of the present invention. The convention will be used wherein light is assumed to be incident upon the top of the material stack in the substrate configuration as illustrated. This generic diagram would be typical of either a CIGS TFPV device or a CZTS TFPV device. The difference being the choice of materials for the absorber layer. A back contact layer, 304, is formed on a substrate, 302. Examples of suitable substrates comprise float glass, low-iron glass, borosilicate glass, flexible glass, specialty glass for high temperature processing, stainless steel, carbon steel, aluminum, copper, titanium, molybdenum, polyimide, plastics, cladded metal foils, etc. Furthermore, the substrates may be processed in many configurations such as single substrate processing, multiple substrate batch processing, in-line continuous processing, in-line “stop and soak” processing, roll-to-roll processing, etc. As used herein, the phrase “back contact” will be understood to be the primary current conductor layer situated between the substrate and the absorber layer in a substrate configuration TFPV device. An example of a common back contact layer material is Mo for CIGS and CZTS. Other types of TFPV devices use different materials for the back contact. As an example, Cu alloys such as Cu/Au, Cu/graphite, Cu/Mo, Cu:ZnTe, etc. are typically used for CdTe TFPV devices and TCO materials such as ZnO, ITO, SnO₂:F, etc. are typically used for a-Si TFPV devices. The back contact layer may be formed by any number of deposition technologies. Examples of suitable deposition technologies comprise PVD (sputtering), evaporation, chemical vapor deposition (CVD), atomic layer deposition (ALD), plating, printing, wet coating, etc. The thickness of the back contact layer is typically between 0.3 um and 1.0 um. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others.

HPC techniques may be applied to the investigation and development of back contact materials for CZTS based TFPV devices. Candidate back contact materials may be deposited with a lateral gradient across a large area substrate and investigated by forming site-isolated regions through mechanical techniques such as scribing or traditional patterning techniques. Alternatively, candidate back contact materials can be deposited within site-isolated regions using deposition through masks, apertures, or other isolation techniques. As discussed previously, a variety of parameters can be varied in a combinatorial manner during the investigation. Parameters which can be varied include, but are not limited to: material, composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

Optionally, a diffusion barrier and/or adhesion-promotion layer (not shown) may be formed between the substrate and the back contact layer. When implemented, the diffusion barrier layer stops the diffusion of impurities from the substrate into the back contact layer, or alternatively, stops the diffusion and reaction of the back contact material with the substrate. Examples of common diffusion barrier and/or adhesion-promotion layers comprise chromium, vanadium, tungsten, nitrides such as tantalum nitride, tungsten nitride, titanium nitride, silicon nitride, zirconium nitride, hafnium nitride, oxy-nitrides such as tantalum oxy-nitride, tungsten oxy-nitride, titanium oxy-nitride, silicon oxy-nitride, zirconium oxy-nitride, hafnium oxy-nitride, oxides such as aluminum oxide, silicon oxide, carbides such as silicon carbide, binary and/or multinary compounds of tungsten, titanium, molybdenum, chromium, vanadium, tantalum, hafnium, zirconium, and/or niobium with/without the inclusion of nitrogen and/or oxygen. The diffusion barrier layer may be formed, partially or completely, from any well known technique such as sputtering, ALD, CVD, evaporation, wet methods such as printing or spraying of inks, screen printing, inkjet printing, slot die coating, gravure printing, wet chemical depositions, or from sol-gel methods such as the coating, drying, and firing of polysilazanes.

A p-type absorber layer, 306, of CIGS (CZTS or other material) is then deposited on top of the back contact layer. The absorber layer may be formed, partially or completely, using a variety of techniques such as PVD (sputtering), co-evaporation, in-line processing, plating, printing or spraying of inks, screen printing, inkjet printing, slot die coating, gravure printing, wet chemical depositions, CVD, etc. Advantageously, the absorber layer is deficient in Cu. The Cu deficiency may be controlled by managing the deposition conditions. Advantageously, a small amount of Na is contained in the absorber present during the absorber growth. The Na may be added by out-diffusion from the SLG substrate or may be purposely added in the form of Na₂Se NaF, sodium alloys of In and/or Ga, or another Na source, prior, during, or after the deposition and/or growth of the absorber layer. Optionally, precursor and/or the absorber layer undergoes a selenization process after formation to convert the precursor to CIGS into a high-quality CIGS semiconductor film. The selenization process involves the exposure of the precursor and/or absorber layer to H₂Se, H₂S, Se vapor, S vapor, or diethylselenide (DESe) at temperatures most typically between 300 C and 700 C. It should be noted that the precursor to CIGS might already contain a chalcogen source (e.g. Se), either as a separate layer, or incorporated into the bulk of the precursor layer. The precursor film can be a stack of layers, or one layer. The precursor layer can be dense, or porous. The precursor film typically contains Cu, In, and Ga. The precursor layer is most commonly deposited by sputtering from e.g. binary copper-gallium and Indium sputter targets. Nevertheless, plating and printing to deposit the metal precursor film containing Cu, In, and/or Ga are used as well. During the selenization process, a layer of Mo(S, Se)₂ (not shown) forms at the back contact/absorber layer interface and forms a fairly good ohmic contact between the two layers.

HPC techniques may be applied to the investigation and development of absorber materials for CZTS based TFPV devices. Candidate absorber materials may be deposited with a lateral gradient across a large area substrate and investigated by forming site-isolated regions through mechanical techniques such as scribing or traditional patterning techniques. Alternatively, candidate absorber materials can be deposited within site-isolated regions using deposition through masks, apertures, or other isolation techniques. As discussed previously, a variety of parameters can be varied in a combinatorial manner during the investigation. Parameters which can be varied include, but are not limited to: material, composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

Alternatively, an interface layer of Mo(S, Se)₂ (not shown) can be deposited at the back contact/absorber layer interface using a variety of well known techniques such as PVD (sputtering), CBD, ALD, plating, etc. The performance of the interface layer is sensitive to materials properties such as crystallinity, grain size, surface roughness, composition, defect concentration, etc. as well as processing parameters such as temperature, deposition rate, thermal treatments, etc.

HPC techniques may be applied to the investigation and development of interface materials for CZTS based TFPV devices. Candidate interface materials may be deposited with a lateral gradient across a large area substrate and investigated by forming site-isolated regions through mechanical techniques such as scribing or traditional patterning techniques. Alternatively, candidate interface materials can be deposited within site-isolated regions using deposition through masks, apertures, or other isolation techniques. As discussed previously, a variety of parameters can be varied in a combinatorial manner during the investigation. Parameters which can be varied include, but are not limited to: material, composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

An n-type buffer layer, 308, is then deposited on top of the absorber layer. Examples of suitable n-type buffer layers comprise CdS, ZnS, In₂S₃, In₂(S, Se)₃, CdZnS, ZnO, Zn(O, S), (Zn, Mg)O, etc. CdS is the material most often used as the n-type buffer layer in CIGS or CZTS TFPV devices. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between 30 nm and 100 nm. The performance of the buffer layer is sensitive to materials properties such as crystallinity, grain size, surface roughness, composition, defect concentration, etc. as well as processing parameters such as temperature, deposition rate, thermal treatments, etc.

HPC techniques may be applied to the investigation and development of buffer materials for CZTS based TFPV devices. Candidate buffer materials may be deposited with a lateral gradient across a large area substrate and investigated by forming site-isolated regions through mechanical techniques such as scribing or traditional patterning techniques. Alternatively, candidate buffer materials can be deposited within site-isolated regions using deposition through masks, apertures, or other isolation techniques. As discussed previously, a variety of parameters can be varied in a combinatorial manner during the investigation. Parameters which can be varied include, but are not limited to: material, composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

Optionally, an intrinsic ZnO (iZnO) layer, 310, is then formed on top of the buffer layer. The iZnO layer is a high resistivity material and forms part of the transparent conductive oxide (TCO) stack that serves as part of the front contact structure. The TCO stack is formed from transparent conductive metal oxide materials and collects charge across the face of the TFPV solar cell and conducts the charge to tabs used to connect the solar cell to external loads. The iZnO layer makes the TFPV solar cell less sensitive to lateral non-uniformities caused by differences in composition or defect concentration in the absorber and/or buffer layers. The iZnO layer is typically between about 0 nm and 150 nm in thickness. The iZnO layer is typically formed using a (reactive) PVD (sputtering) technique or CVD technique, but can be deposited by plating or printing as well.

A low resistivity top TCO layer, 312, (examples include Al:ZnO (AZO), InSnO (ITO), InZnO, B:ZnO, Ga:ZnO, F:ZnO, F:SnO₂, etc.) is formed on top of the iZnO layer. The top TCO layer is typically between 0.25 um and 1.0 um in thickness. The top TCO layer is typically formed using a (reactive) PVD (sputtering) technique or CVD technique. Optionally, the transparent top electrode can be printed or wet-coated from (e.g. silver) nano-wires, carbon nanotubes, and the like.

HPC techniques may be applied to the investigation and development of TCO stack materials for CZTS based TFPV devices. Candidate TCO stack materials may be deposited with a lateral gradient across a large area substrate and investigated by forming site-isolated regions through mechanical techniques such as scribing or traditional patterning techniques. Alternatively, candidate TCO stack materials can be deposited within site-isolated regions using deposition through masks, apertures, or other isolation techniques. As discussed previously, a variety of parameters can be varied in a combinatorial manner during the investigation. Parameters which can be varied include, but are not limited to: material, composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

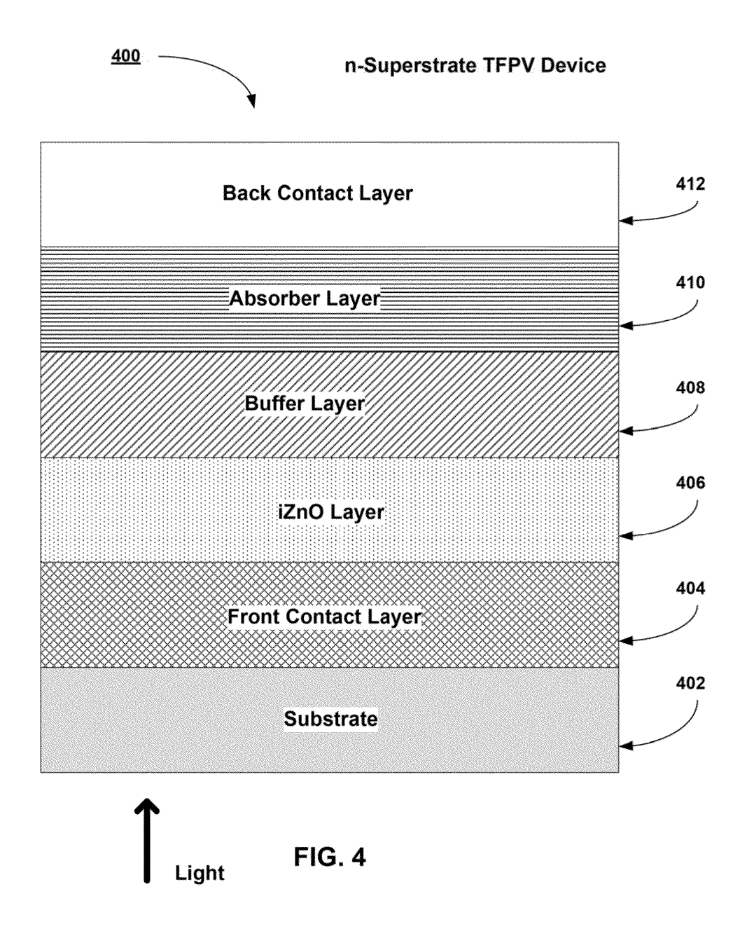

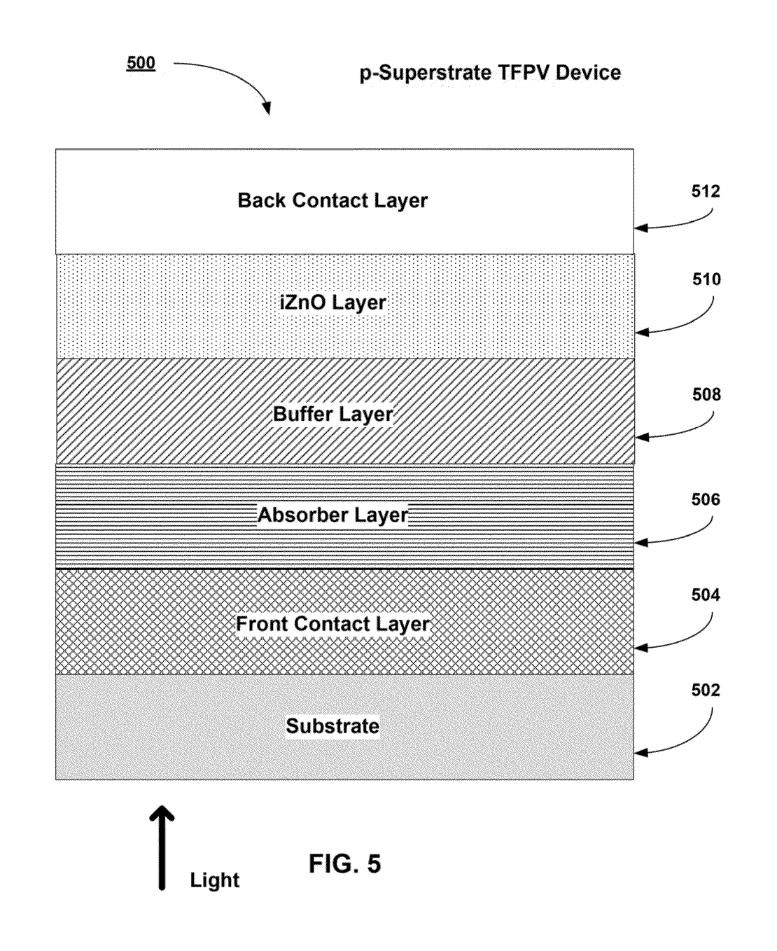

FIG. 4 illustrates a simple CIGS TFPV device material stack, 400, consistent with some embodiments of the present invention. The CIGS TFPV device illustrated in FIG. 4 is shown in a superstrate configuration wherein the glass substrate faces the incident sunlight. The convention will be used wherein light is assumed to be incident upon the substrate and material stack as illustrated. As used herein, this configuration will be labeled a “n-superstrate” configuration to denote that the n-type layer (i.e. buffer layer) is closest to the incident light. This label is to distinguish the configuration from an alternate configuration described with respect to FIG. 5 below. The formation of the CIGS TFPV device will be described starting with the substrate. A similar structure and similar method would also be applicable to the formation of a CZTS TFPV solar cell fabricated with a superstrate configuration. Examples of suitable substrates comprise float glass, low-iron glass, borosilicate glass, flexible glass, specialty glass for high temperature processing, polyimide, plastics, etc. Furthermore, the substrates may be processed in many configurations such as single substrate processing, multiple substrate batch processing, in-line continuous processing, roll-to-roll processing, etc.

A low resistivity bottom TCO front contact layer, 404, (examples include Al:ZnO (AZO), InSnO (ITO), InZnO, B:ZnO, Ga:ZnO, F:ZnO, F:SnO₂, etc.) is formed on top of the substrate, 402. As used herein, the phrase “front contact” will be understood to be the primary current conductor layer situated between the substrate and the buffer layer in a superstrate configuration TFPV device. The bottom TCO layer is typically between 0.3 um and 2.0 um in thickness. The bottom TCO layer is typically formed using a reactive PVD (sputtering) technique or CVD technique.

Optionally, a diffusion barrier and/or adhesion-promotion layer (not shown) may be formed between the substrate, 402, and the front contact layer, 404. When implemented, the diffusion barrier layer stops the diffusion of impurities from the substrate into the TCO, or alternatively, stops the diffusion and reaction of the TCO material and above layers with the substrate. Examples of common diffusion barrier and/or adhesion-promotion layers comprise chromium, vanadium, tungsten, nitrides such as tantalum nitride, tungsten nitride, titanium nitride, silicon nitride, zirconium nitride, hafnium nitride, oxy-nitrides such as tantalum oxy-nitride, tungsten oxy-nitride, titanium oxy-nitride, silicon oxy-nitride, zirconium oxy-nitride, hafnium oxy-nitride, oxides such as aluminum oxide, silicon oxide, carbides such as silicon carbide, binary and/or multinary compounds of tungsten, titanium, molybdenum, chromium, vanadium, tantalum, hafnium, zirconium, and/or niobium with/without the inclusion of nitrogen and/or oxygen. It should be understood that the diffusion barrier layer composition and thickness are optimized for optical transparency as necessary for the superstrate configuration. The diffusion barrier layer may be formed from any well known technique such as sputtering, ALD, CVD, evaporation, wet methods such as printing or spraying of inks, screen printing, inkjet printing, slot die coating, gravure printing, wet chemical depositions, or from sol-gel methods, such as the coating, drying, and firing of polysilazanes.

An intrinsic iZnO layer, 406, is then formed on top of the TCO layer. The iZnO layer is a high resistivity material and forms part of the transparent conductive oxide (TCO) stack that serves as part of the front contact structure. The iZnO layer makes the TFPV device less sensitive to lateral non-uniformities caused by differences in composition or defect concentration in the absorber and/or buffer layers. The iZnO layer is typically between about 0 nm and 150 nm in thickness. The iZnO layer is typically formed using a reactive PVD (sputtering) technique or CVD technique.

An n-type buffer layer, 408, is then deposited on top of the iZnO layer, 406. Examples of suitable n-type buffer layers comprise CdS, ZnS, In₂S₃, In₂(S, Se)₃, CdZnS, ZnO, Zn(O, S), (Zn, Mg)O, etc. CdS is the material most often used as the n-type buffer layer in CIGS or CZTS TFPV devices. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between 30 nm and 100 nm. The performance of the buffer layer is sensitive to materials properties such as crystallinity, grain size, surface roughness, composition, defect concentration, etc. as well as processing parameters such as temperature, deposition rate, thermal treatments, etc.

A p-type absorber layer, 410, of CIGS (CZTS or other IB-IIIA-VIA material) is then deposited on top of the buffer layer. The absorber layer may be formed, partially or completely, using a variety of techniques such as PVD (sputtering), co-evaporation, in-line processing, plating, printing or spraying of inks, screen printing, inkjet printing, slot die coating, gravure printing, wet chemical depositions, CVD, etc. Advantageously, the absorber layer is deficient in Cu. The Cu deficiency may be controlled by managing the deposition conditions. Advantageously, a small amount of Na is present during the growth of the absorber. The Na may be purposely added in the form of Na₂Se or another Na source, prior, during, or after the deposition and/or growth of the absorber layer. Optionally, the precursor and/or absorber layer undergoes a selenization process after formation to convert the precursor to CIGS into a high-quality CIGS semiconductor film. The selenization process involves the exposure of the precursor and/or absorber layer to H₂Se, H₂S, Se vapor, S vapor, or diethylselenide (DESe) at temperatures most typically between 300 C and 700 C. It should be noted that the precursor to CIGS might already contain a chalcogen source (e.g. Se), either as a separate layer, or incorporated into the bulk of the precursor layer. The precursor film can be a stack of layers, or one layer. The precursor layer can be dense, or porous. The precursor film typically contains Cu, In, and Ga. The precursor layer is most commonly deposited by sputtering from e.g. binary Cu—Ga and In sputter targets. Nevertheless, plating and printing to deposit the metal precursor film containing Cu, In, and/or Ga are used as well. During subsequent processing, a layer of Mo(S, Se)₂ (not shown) is formed at the back contact/absorber layer interface and forms a fairly good ohmic contact between the two layers. The thickness of the absorber layer is typically between 1.0 um and 3.0 um. The performance of the absorber layer is sensitive to materials properties such as crystallinity, grain size, surface roughness, composition, defect concentration, etc. as well as processing parameters such as temperature, deposition rate, thermal treatments, etc.

A back contact layer, 412, is formed on absorber layer, 410. An example of a common back contact layer material is Mo for CIGS and CZTS. The back contact layer may be formed by any number of deposition technologies. Examples of suitable deposition technologies comprise PVD (sputtering), evaporation, chemical vapor deposition (CVD), atomic layer deposition (ALD), plating, etc. The thickness of the back contact layer is typically between 0.3 um and 1.0 um. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others. Other types of TFPV devices use different materials for the back contact. As an example, Cu alloys such as Cu/Au, Cu/graphite, Cu/Mo, Cu:ZnTe, etc. are typically used for CdTe TFPV devices and TCO materials such as ZnO, ITO, SnO₂:F, etc. are typically used for a-Si TFPV devices.

As discussed previously with respect to FIG. 3, candidate materials for layers such as the back contact layer, interface layer, absorber layer, buffer layer, and TCO stack for use in the n-superstrate configuration of CZTS based TFPV devices can be investigated using the HPC techniques described herein.

FIG. 5 illustrates a simple CIGS TFPV device material stack, 500, consistent with some embodiments of the present invention. The CIGS TFPV device illustrated in FIG. 5 is shown in a superstrate configuration wherein the glass substrate faces the incident sunlight. The convention will be used wherein light is assumed to be incident upon the substrate and material stack as illustrated. As used herein, this configuration will be labeled a “p-superstrate” configuration to denote that the p-type layer (i.e. absorber layer) is closest to the incident light. This label is to distinguish the configuration from the alternate configuration described with respect to FIG. 4 previously. The formation of the CIGS TFPV device will be described starting with the substrate. A similar structure and similar method would also be applicable to the formation of a CZTS TFPV solar cell fabricated with a superstrate configuration. Examples of suitable substrates comprise float glass, low-iron glass, borosilicate glass, flexible glass, specialty glass for high temperature processing, polyimide, plastics, etc. Furthermore, the substrates may be processed in many configurations such as single substrate processing, multiple substrate batch processing, in-line continuous processing, roll-to-roll processing, etc.

A low resistivity bottom TCO front contact layer, 504, is formed on top of the substrate, 502. As used herein, the phrase “front contact” will be understood to be the primary current conductor layer situated between the substrate and the absorber layer in a superstrate configuration TFPV device. The bottom TCO layer is typically between 0.3 um and 2.0 um in thickness. The bottom TCO layer is typically formed using a reactive PVD (sputtering) technique or CVD technique. The TCO can be a p-type TCO, (e.g. ternary-based oxide in the family of CO₃O₄-based spinels, like Co₂ZnO₄ and Co₂NiO₄). Nevertheless, it should be understood that an n-type TCO with an additional layer (e.g. of MoSe₂) between the TCO and the absorber can be used as well. Furthermore, the TCO might be a bi- or multi-layer of an n-type TCO in contact with the substrate, followed by an ultrathin metal layer, (e.g. like Ag), followed by a thin p-type TCO in contact with the absorber layer, with/without an additional MoSe₂ layer between the p-type TCO and the absorber layer.

Optionally, a diffusion barrier and/or adhesion-promotion layer (not shown) may be formed between the substrate, 502, and the front contact layer, 504. When implemented, the diffusion barrier and/or adhesion-promotion layer stops the diffusion of impurities from the substrate into the TCO, or alternatively, stops the diffusion and reaction of the TCO material and above layers with the substrate. Examples of common diffusion barrier and/or adhesion-promotion layers comprise chromium, vanadium, tungsten, nitrides such as tantalum nitride, tungsten nitride, titanium nitride, silicon nitride, zirconium nitride, hafnium nitride, oxy-nitrides such as tantalum oxy-nitride, tungsten oxy-nitride, titanium oxy-nitride, silicon oxy-nitride, zirconium oxy-nitride, hafnium oxy-nitride, oxides such as aluminum oxide, silicon oxide, carbides such as silicon carbide, binary and/or multinary compounds of tungsten, titanium, molybdenum, chromium, vanadium, tantalum, hafnium, zirconium, and/or niobium with/without the inclusion of nitrogen and/or oxygen. It should be understood that the diffusion barrier and/or adhesion-promotion layer composition and thickness are optimized for optical transparency as necessary for the superstrate configuration. The diffusion barrier and/or adhesion-promotion layer may be formed from any well known technique such as sputtering, ALD, CVD, evaporation, wet methods such as printing or spraying of inks, screen printing, inkjet printing, slot die coating, gravure printing, wet chemical depositions, or from sol-gel methods such as the coating, drying, and firing of polysilazanes.

A p-type absorber layer, 506, of CIGS (CZTS or other absorber material) is then deposited on top of the front contact layer. The absorber layer may be formed, partially, or completely, using a variety of techniques such as PVD (sputtering), co-evaporation, in-line processing, plating, printing or spraying of inks, screen printing, inkjet printing, slot die coating, gravure printing, wet chemical depositions, CVD, etc. Advantageously, the absorber layer is deficient in Cu. The Cu deficiency may be controlled by managing the deposition conditions. Advantageously, a small amount of Na is present during the growth of the absorber. The Na may be purposely added in the form of Na₂Se or another Na source, prior, during, or after the deposition of the precursor and/or absorber layer. Typically, the precursor and/or absorber layer undergoes a chalcogenization (e.g. selenization) process after formation to convert the precursor to CIGS into a high-quality CIGS semiconductor film. The chalcogenization process involves the exposure of the precursor and/or absorber layer to H₂Se, H₂S, Se vapor, S vapor, or diethylselenide (DESe) at temperatures most typically between 300 C and 700 C. It should be noted that the precursor to CIGS might already contain a chalcogen source (e.g. Se), either as a separate layer, or incorporated into the bulk of the precursor layer. The precursor film can be a stack of layers, or one layer. The precursor layer can be dense, or porous. The precursor film typically contains Cu, In, and Ga. The precursor layer is most commonly deposited by sputtering from e.g. binary copper-gallium and Indium sputter targets. Nevertheless, plating and printing to deposit the metal precursor film containing Cu, In, and/or Ga are used as well. The thickness of the absorber layer is typically between 1.0 um and 3.0 um. The performance of the absorber layer is sensitive to materials properties such as crystallinity, grain size, surface roughness, composition, defect concentration, etc. as well as processing parameters such as temperature, deposition rate, thermal treatments, etc.

An n-type buffer layer, 508, is then deposited on top of the absorber layer. Examples of suitable n-type buffer layers comprise CdS, ZnS, In₂S₃, In₂(S, Se)₃, CdZnS, ZnO, Zn(O, S), (Zn, Mg)O, etc. CdS is the material most often used as the n-type buffer layer in CIGS or CZTS TFPV devices. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between 30 nm and 100 nm. The performance of the buffer layer is sensitive to materials properties such as crystallinity, grain size, surface roughness, composition, defect concentration, etc. as well as processing parameters such as temperature, deposition rate, thermal treatments, etc.

An intrinsic iZnO layer, 510, is then formed on top of the buffer layer. The iZnO layer is a high resistivity material and forms part of the back contact structure. The iZnO layer makes the TFPV device less sensitive to lateral non-uniformities caused by differences in composition or defect concentration in the absorber and/or buffer layers. The iZnO layer is typically between about 0 nm and 150 nm in thickness. The iZnO layer is typically formed using a reactive PVD (sputtering) technique or CVD technique.

A back contact layer, 512, is formed on intrinsic iZnO layer, 510. An example of a suitable back contact layer material is a thin n-type TCO followed by Ni and/or Al. The back contact layer may be formed by any number of deposition technologies. Examples of suitable deposition technologies comprise PVD (sputtering), evaporation, chemical vapor deposition (CVD), atomic layer deposition (ALD), plating, etc. The thickness of the back contact layer is typically between 0.3 um and 1.0 um. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others. Other types of TFPV devices use different materials for the back contact. As an example, Cu alloys such as Cu/Au, Cu/graphite, Cu/Mo, Cu:ZnTe, etc. are typically used for CdTe TFPV devices and TCO materials such as ZnO, ITO, SnO₂:F, etc. are typically used for a-Si TFPV devices.

The film stack described above is just one example of a film stack that can be used for TFPV devices. As an example, another substrate film stack (i.e. similar configuration as FIG. 3) might be:

Substrate/AZO/Mo/CIGS/CdS/iZnO/AZO. As an example, another p-superstrate film stack (i.e. similar configuration as FIG. 5) might be:
substrate/barrier/ZnO:Al/Mo/CIGS/CdS/iZnO/ZnO:Al/Al. The detailed film stack configuration is not meant to be limiting, but simply serves as an example of the implementation of embodiments of the present invention.

As discussed previously with respect to FIG. 3, candidate materials for layers such as the back contact layer, interface layer, absorber layer, buffer layer, and TCO stack for use in the p-superstrate configuration of CZTS based TFPV devices can be investigated using the HPC techniques described herein.

The efficiency of a TFPV device depends on the bandgap of the absorber material. The goal is to have the bandgap tuned to the energy range of the photons incident on the device. The theoretical upper limit for a single p-n junction solar cell has been calculated to be about 33 to 34%. The peak in the efficiency occurs for values of the bandgap between 1.0 eV and 1.5 eV, and more specifically between 1.3 eV and 1.5 eV. The bandgap for CIGSe films varies smoothly from CISe=1.00 (i.e. Ga/(Ga+In)=0.0) to CGSe=1.68 (i.e. Ga/(Ga+In)=1.0). The region of interest is from Ga/(Ga+In)=0.4 (˜1.23 eV) to Ga/(Ga+In)=0.7 (˜1.45 eV).

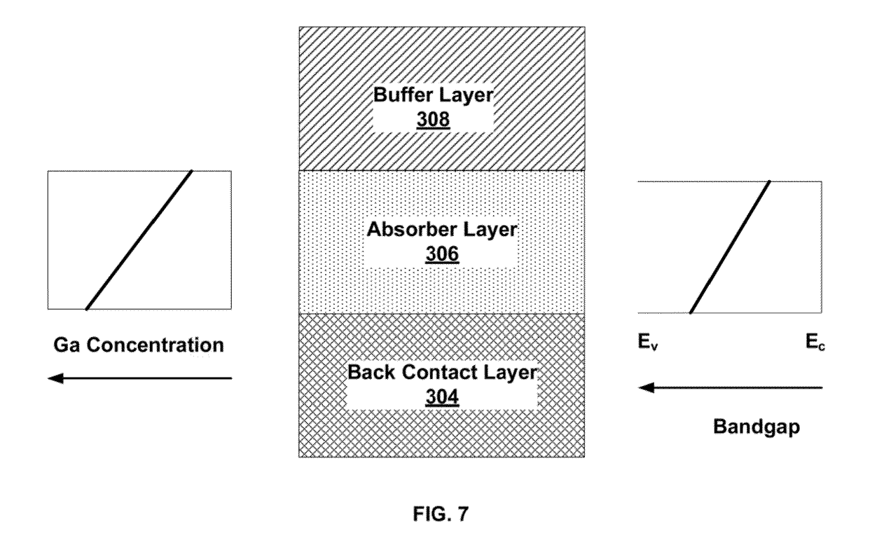

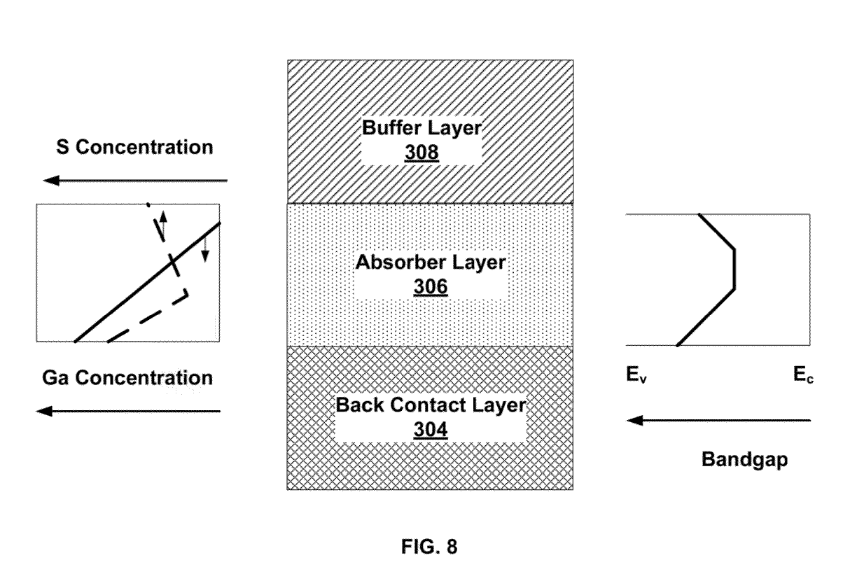

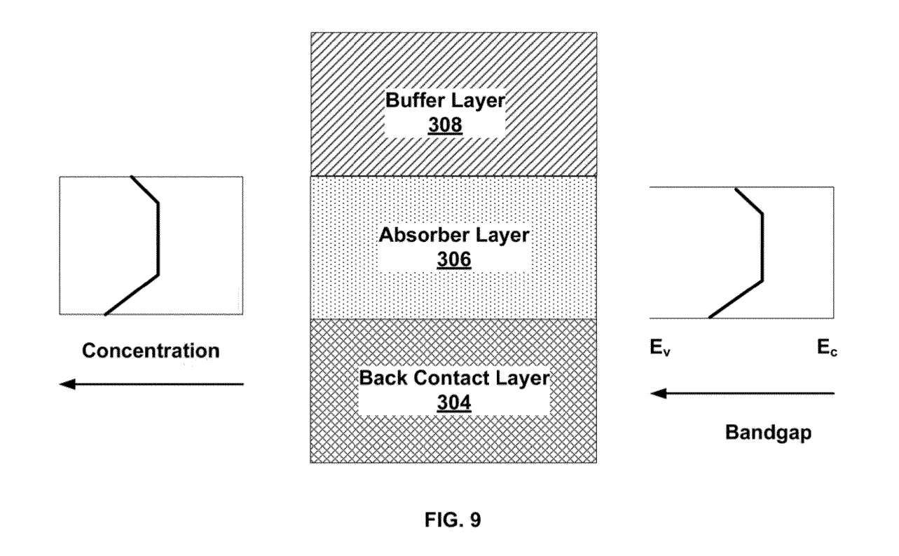

Group-IB-IIIA-VIA (e.g. CIGSe-based) TFPV devices can reach efficiencies beyond 15% without bandgap (Eg) grading (i.e. a flat Eg profile). A flat bandgap is illustrated in FIG. 6. Higher efficiencies have been obtained by single grading of CIGSe with a gradual drop in Ga/(In +Ga) from the back contact to the front, so without a “notch” (also called saddle, or double grading). A single graded bandgap is illustrated in FIG. 7. Forming CIGSe absorbers with a bandgap grading containing a “notch” (also called saddle profile or double grading) has allowed efficiencies above 18% to be realized. Bandgap grading via compositional grading, (most commonly done by Ga/(In +Ga), and/or S/(S+Se)) can produce efficiencies over 17%. A double graded bandgap using both Ga and S is illustrated in FIGS. 8 and 9. The efficiency for the double grading increased from 16%, via a few intermediate champions, to the current record of 20.3% by compositional grading Ga/(In +Ga) for CIGSe.

The improvements in efficiency for CIGSe TFPV devices over the past few decades can be divided into three categories:

First: Material quality improvement by reducing the electronically-active defects and optimizing doping profiles, thereby reducing recombination, and as such, improving open circuit voltage (V_{oc}) and the fill factor (FF).

Second: Bandgap (composition) depth profile improvements, thereby reducing recombination while maintaining photo-generation, and thereby obtaining both a high FF, a high V_{oc} while maintaining the short circuit current density (J_{sc}).

Third: Improvements in junction partner, top electrode, cell design, grid design, and anti-reflection coatings, all contributing by reducing optical losses, and as such, improving J_{sc}.

It should be noted that in addition to CIGSe bulk improvements, like defect chemistry, the homogeneity of the absorber has improved tremendously, reducing the number of weak diodes in a CIGSe device. Furthermore, while improving the bulk of the layers, improved queue time control and interface engineering has resulted in reducing interface recombination, and assisted in improving FF and V_{oc}.

The 20% laboratory champions have been achieved by a long co-evaporation batch process which has proven difficult to transfer economically to the manufacturing floor, where High-Volume Manufacturing (HVM) requires an in-line process that is (i) fast (<5 min) using low-cost equipment, (ii) has high up-time, (iii) high yield, and (iv) high materials utilization to achieve a cost-competitive growth process. Unfortunately, in-line HVM processes have exhibited challenges in all of these metrics ((i)-(iv)), in addition to uniformity challenges on large area substrates.

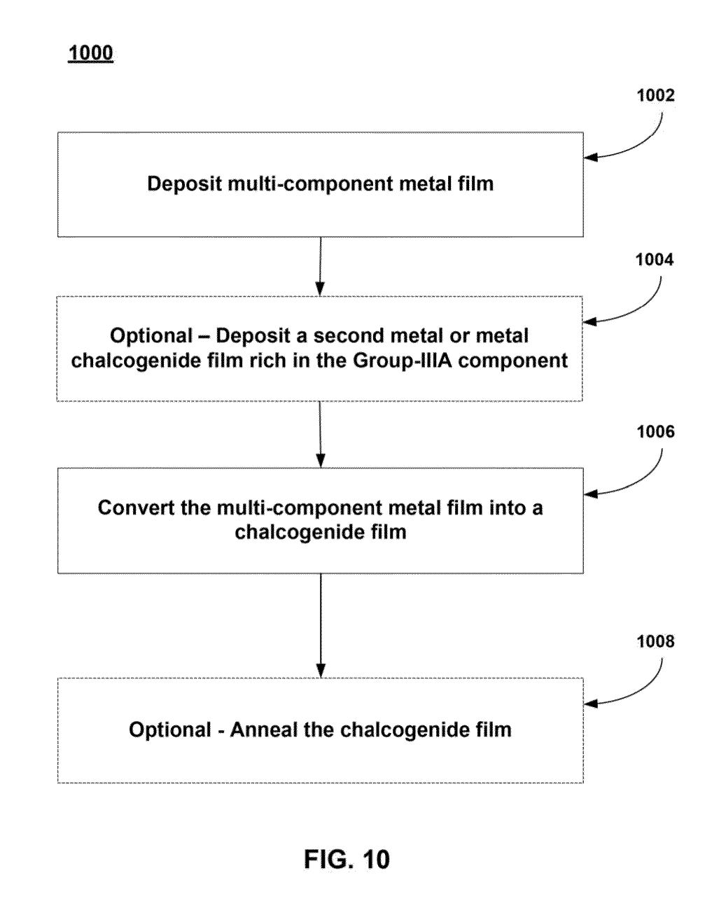

One way of grading CIGS or CZTS materials is by a 2-step approach as illustrated in FIG. 10. In step 1002, “metal precursor” films are deposited. For CIGS-like absorbers, the metal precursor films comprise Group IB and Group-IIIA metals. For CZTS-like absorbers, the metal precursor films comprise Group IB, Group-IIB, and Group-IVA metals. In the case of CIGS absorbers, the metal precursor films comprise Cu, In, and Ga, with/without a Na source. This metal film needs to be converted to a chalcogenide to form the absorber layer. The metal precursor film is converted to a chalcogenide by heating the film in the presence of a source of one or more the Group-VIA elements as indicated in step 1006. In the case of CZTS absorbers, the metal precursor films comprise Cu, Zn, and Sn, with/without a Na source. This metal film needs to be converted to a chalcogenide to form the absorber layer. The metal precursor film is converted to a chalcogenide by heating the film in the presence of a source of one or more the Group-VIA elements as indicated in step 1006.

Optionally, the chalcogenide film can be annealed as indicated in step 1008. For CIGS-type absorbers, a variation of the 2-step process comprises depositing a second, thin Group-IIIA film or Group-IIIA chalcogenide material (e.g. GaSe) on top of the metal precursor film as illustrated in step 1004. In this variation, the Group-IIIA metal is bound in the chalcogenide and its diffusion toward the back of the absorber layer is retarded, yielding a higher concentration of the Group-IIIA metal at the front of the absorber layer. This results in a double-graded composition of the Group-IIIA metal and a double-graded bandgap.

Generally, the 2-step method may comprise more than two steps when various wet chemical and/or conversion methods (e.g. for densification or contaminant removal) and/or deposition steps (e.g. for a separate chalcogen layer as discussed previously) are used to form the metal precursor film. As discussed above, the metal precursor film may be a single layer or may be formed from multiple layers, it may be dense or porous.

The highest efficiencies for 2-step CIG(S)Se have been achieved by converting PVD (sputtered) Cu(In, Ga) into CIG(S)Se by a chalcogenization process where the Cu(In, Ga) film is both chalcogenized and sulfurized. Unfortunately, CIG(S)Se formed using a 2-step process has not yet achieved >20% efficiency, and lags ˜2% behind the laboratory champion of CIGSe. This is mainly due to the fact that it is challenging to control both bandgap grading and maintain a high minority carrier lifetime when sulfur is introduced.

Unfortunately, the traditional 2-step approach based on Cu(In, Ga) followed by selenization (without introducing sulfur) has so far only resulted in flat bandgap profiles, or single-graded CIGSe, resulting in efficiencies <16.0%.

It should be noted that the above cited efficiencies are laboratory champion efficiencies for 0.5 cm² solar cells, not to be confused with commercially available, average, solar panel efficiencies which are typically 5-6% lower than laboratory champions, due to a combination of non-uniformity within solar cells, mismatch between series-connected cells, absorption losses in thick TCO layers, encapsulant, and glass, scribe and edge losses, and additional series resistance, all in addition to running a different process in the factory compared to the laboratory.

One of the main challenges for 2-step selenization is to control the phase separation in the Cu-poor film. High efficiency CIG(S)Se or CZTS requires a Cu-poor (p-type) CIGSe or CZTS film. Cu-poor Cu(In, Ga) or CZTS metal films prior to chalcogenization are multi-phasic (2 or more separate phases present in the film), and as such, are hard to deposit in a homogeneous fashion that provides a conformal, smooth, uniform Cu(In, Ga) or CZTS film, especially, due to the fact that indium-rich phases have the tendency to agglomerate due to poor wetting of underlying surfaces. Laterally uniform Cu(In, Ga) and Cu(In, Ga)Se₂ films are needed to avoid the formation of weak diodes that reduce the overall solar cell efficiency.

The agglomeration of In is typically minimized by reducing the dynamic deposition rate, and/or controlling the substrate temperature during PVD, and/or introducing a multi-layer stack of alternating layers of In-rich and Cu-rich layers, all resulting in additional Capital Expenditure (CapEx). Other approaches try to avoid the phase separation by depositing a chalcogenide precursor film by PVD from binary, or multinary chalcogenide targets which results in a CapEx investment typically >3× higher than for PVD-CIG due to the deposition of a film ˜3× thicker with a lower dynamic deposition rate. In addition, direct material costs for the chalcogenide targets are higher than for the metallic targets.

A second challenge for 2-step selenization is to control bandgap grading in depth in the final CIGSe film by Ga/(In +Ga) compositional grading. Ga-rich phases chalcogenize slower than Cu and In, and therefore, most of the Ga collects at the back of the CIGSe film resulting in a single-graded CIGSe film. One way to avoid this Ga migration and maintain a flat Ga distribution is to extending the selenization time (>30 min), and go to high temperatures (550-600 C). However, these temperatures are not compatible with all low-temperature, low-cost substrates. Furthermore, this has not resulted in any double-graded CIGSe (>20%).

A third challenge for 2-step selenization is to prevent adhesion failure of the CIGSe film due to stress resulting from the expansion from Cu(In, Ga) to CIGSe at elevated temperature. The expansion from the metal film to the chalcogenide film can be 2.5-3.0× in volume. Additionally, the overall stack of layers may have very different coefficients of thermal expansion, thickness, and Young's modulus.

So far, back grading has been done by compositional grading of Gallium (Ga/(In +Ga)).

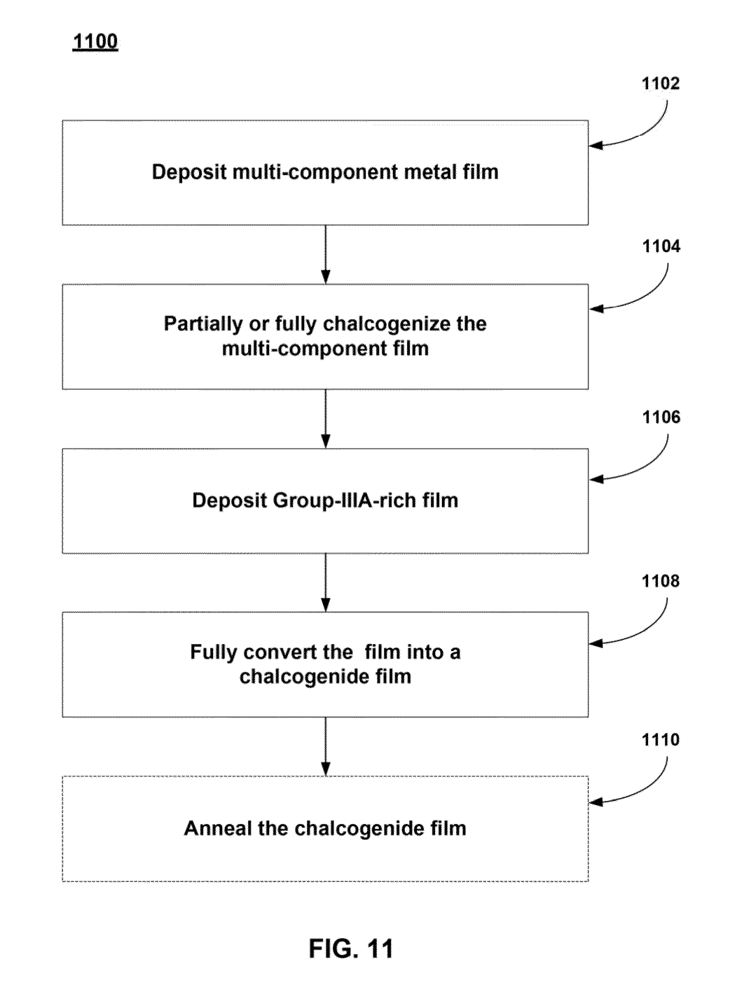

A second way of grading CIGS (or CZTS) materials is by a 4-step approach as illustrated in FIG. 11. In step 1102, “metal precursor” films are deposited. For CIGS-like absorbers, the metal precursor films comprise Group IB and Group-IIIA metals. For CZTS-like absorbers, the metal precursor films comprise Group IB, Group-IIB, and Group-IVA metals. In the case of CIGS absorbers, the metals comprise Cu, In, and Ga, with/without a Na source. This metal precursor film needs to be converted to a chalcogenide to form the absorber layer. The metal precursor film is converted to a chalcogenide by heating the film in the presence of a source of one or more the Group-VIA elements as indicated in step 1104. In the case of CZTS absorbers, the metals comprise Cu, Zn, and Sn, with/without a Na source. This metal precursor film needs to be converted to a chalcogenide to form the absorber layer. The metal precursor film is converted to a chalcogenide by heating the film in the presence of a source of one or more the Group-VIA elements as indicated in step 1104. In step 1106, a metal-rich layer (e.g. Group IIIA for CIGS-type absorbers, Group IIB for CZTS-type absorbers) is formed on the surface of the partially or fully chalcogenized chalcogenide film. In step 1106, the metal-rich layer may be a metal material or may be a metal chalcogenide material (e.g. metal oxide, metal sulfide, metal selenide, metal telluride, etc.). In step 1108, the entire absorber stack is converted using a chalcogenization process. The chalcogenization process may include an additional anneal step at the end to improve the device performance as illustrated in step 1110. Details of a chalcogenization process including an additional anneal step are described in U.S. patent application Ser. No. 13/283,225, filed on Oct. 27, 2011, and U.S. patent application Ser. No. 13/461,495, filed on May 1, 2012, each of which is herein incorporated by reference for all purposes.

Generally, the 4-step method may comprise additional steps when various wet chemical and/or conversion methods (e.g. for densification or contaminant removal) and/or deposition steps are used to form the metal precursor film and/or the metal rich layer. As discussed above, the metal precursor film and/or the metal rich layer may each be a single layer or may each be formed from multiple layers.

In each of the multi-step methods described above and the examples to be disclosed below, the performance of the absorber layer can be improved by incorporating a small amount (i.e. 0.1 atomic %) of Na into the absorber material. The incorporation of Na results in improved film morphology, higher conductivity, and beneficial changes in the defect distribution within the absorber material. The Na may be introduced in a number of ways. The Na may diffuse out of the glass substrate, out of a layer disposed between the glass substrate and the back contact (e.g. a Na containing sol-gel layer formed under the back contact), or out of the back contact (e.g. molybdenum doped with a Na salt). The Na may be introduced from a separate Na containing layer formed on top of the back contact. The Na may be introduced by incorporating a Na source in the Cu(In, Ga) or Cu(Zn, Sn) precursor film. Examples of suitable Na sources comprise Na₂Se, Na₂O₂, NaF, Na₂S, etc. The Na may be introduced from a separate Na containing layer formed on top of the precursor film. The Na may be introduced from a separate Na containing layer formed on top of the partially or completely chalcogenized CIGS film. The Na may be introduced by incorporating a Na source in the Ga-rich film. The Na may be introduced from a separate Na containing layer formed on top of the Ga-rich film. The Na may be introduced by incorporating a Na precursor during the selenization step. The Na may be introduced after the final chalcogenization step, followed by a heat treatment. The Na may be introduced by combining any of these methods as required to improve the performance of the absorber layer.

In each of the multi-step methods described above and the examples to be disclosed below, a metal precursor film(s) is deposited. Typically, the precursor material will deviate in shape, size, composition, homogeneity, crystallinity, or some combination of these parameters from the absorber material that is ultimately formed as a result of the method. As mentioned previously, the metal precursor film(s) can comprise multiple layers. These layers may be deposited by the same or by different deposition techniques. It should be noted that similar Group IA, and/or Group IIA elements like K, and Ca might be used instead of sodium.

The metal precursor film(s) can be deposited using a number of techniques. Examples comprise dry deposition techniques such as batch or in-line (co)evaporation, batch or in-line PVD (sputtering), ALD, CVD, Plasma enhanced CVD (PECVD), Plasma enhanced ALD (PEALD), atmospheric pressure CVD (APCVD), ultra-fast atmospheric ALD, plating, printing or spraying of inks, screen printing, inkjet printing, slot die coating, gravure printing, wet chemical depositions, etc.

In the discussions of the materials and layers discussed with respect to FIGS. 3-5, typical deposition methods were listed for each layer. Additionally, in each case, all of the materials discussed above and the methods to follow can be deposited using deposition techniques based on nanopowders, nanoparticles, etc. Nanoparticles are sometimes defined as particles with sizes between 1 nm and 100 nm. As used herein, the term “nanoparticles” will be understood to cover all particle sizes from 1 nm up to 1000 nm. Nanoparticles can be formed from metal, dielectric, or semiconductor materials as well as hybrid structures wherein the core of the nanoparticles is different from an outer shell of the nanoparticles. The formation of nanoparticles is well understood.

Nanoparticles may be delivered in a wide variety of delivery systems such as liquids, inks, pastes, sol-gels, colloids, etc. Further, they may be applied using common techniques such as spin coating, dipping, spraying, ink-jet printing, screen printing, roller coating, casting, curtain coating, slot die coating, capillary coating, etc. The benefit of these techniques is that they are scalable to large area substrates, are scalable to high volume manufacturing, have acceptable material utilization rates, and are inexpensive. Generally, the nanoparticle solution or paste must be heated to evaporate the carrier medium. Additionally, the resulting nanoparticles film may be annealed or otherwise treated to influence properties such as density, conductivity, reflectivity, roughness, etc.

Other examples of deposition techniques also comprise wet deposition techniques wherein the metal precursor materials are delivered using a liquid vehicle or carrier. The liquid vehicle (e.g. solvent, solvent mixture, and/or water) contains the metal precursor material in the form of particles, nanoparticles, nanocolloids, nanoflakes, microflakes, spherical and/or non-sperical particles, dissolved precursor materials, polymeric precursor materials, or combinations thereof. The particles may have a homogeneous composition, an inhomogeneous composition, or may have a shell comprising a different composition from the core of the particle. Various types of particles may be combined within the same liquid vehicle. The particles may be elemental, binary, or multinary compounds (e.g. metal chalcogenides). The particles may be salts or undissolved polymers with inorganic ionic groups. The particles may be “grown” using various well known wet chemical processes, or may be produced by grinding or milling larger sized particles.

There are many techniques that can be used to deliver the liquid vehicle containing the particles to the substrate. Examples of suitable techniques comprise printing (e.g. inkjet printing, screen printing, gravure printing, and the like), wet coating (e.g. slot-die coating, curtain coating, capillary coating, roll coating, and the like), and spraying (e.g. ultrasonic spraying, spray pyrolysis, and the like). Advantageously, depositions using these techniques occur at atmospheric pressure and at temperatures between room temperature and 90° C. Additionally, it is advantageous if the depositions using these techniques can be accomplished without the use of electromagnetic sources such as ultraviolet (UV) light and/or electric fields.

Examples of other techniques that can be used to deposit the metal precursor materials comprise ion-layer-gas-reaction (ILGAR), hot liquid metal deposition, sol-gel techniques, metal emulsions, electroplating, electroless plating, chemical bath deposition (CBD), and chemical surface deposition (CSD).

One or more wet chemical surface or film treatments may be used to remove unwanted material, replace unwanted material with wanted material (e.g. by ionic exchange), convert the film or surface, or add material to the film. Advantageously, treatments using these techniques occur at atmospheric pressure and at temperatures between room temperature and 90° C. Additionally, it is advantageous if the treatments using these techniques can be accomplished without the use of electromagnetic sources such as ultraviolet (UV) light and/or electric fields. Examples of wet chemical surface or film treatments comprise KCN-etch, Br₂/MeOH etch, partial electrolyte treatments, acid etch, alkaline etch, NH₃ treatment, etc.

One or more heat treatments will be required after the deposition of the metal precursor materials using one of the deposition techniques described previously to convert the metal precursor materials into high quality, dense, semiconductor materials. As discussed previously, collectively, these processes will be called chalcogenization, two examples of which are selenization, and sulfurization. Typically, the heat treatment will further require a suitable atmosphere such as N₂, H₂, CO, H₂Se, H₂S, H₂Te, diethyl selenide (DESe), diethyl telluride (DETe), Se, S, Te, or combinations thereof. The contaminants inherently present in inks or liquid vehicle formulations might be partially or fully removed by atmospheric plasma glow discharge treatments, UV-ozone treatments, laser treatments, treatments with weak (in)organic acids, etc.

The most common conversion method involves subjecting the metal precursor materials to a chalcogenization process wherein the metal precursor materials are converted to chalcogenide materials. The substrate and the metal precursor materials are heated in the presence of a suitable chalcogen source (e.g. H₂Se, H₂S, H₂Te, diethyl selenide (DESe), diethyl telluride (DETe), Se, S, Te, or combinations thereof, etc.) in an atmosphere with a low O₂ and/or low H₂O content. The atmosphere typically comprises inert gases such as N₂ and/or Ar. Alternatively, the chalcogen (i.e. Se, S, Te) may be deposited as a solid (either elemental or as a suitable compound) on the surface of the metal precursor materials prior to the heat treatment. The chalcogen solid may be deposited using a vacuum process, an atmospheric process, a printing process, a wet coating process, other solution based processes, or some combination thereof.

Any suitable heat treating technique may be used during the conversion process. Examples comprise convective heating, conductive heating, radiative heating, or combinations thereof. Furthermore, common heating methods comprise infra-red (IR) lamps, resistive heating, muffle heating, strip heating, laser heating, flash lamps, etc.

The conversion process may be performed in a batch system or an in-line system. In the case of an in-line system, the substrate may move through the system in a continuous manner or may move through the system in a “stop-and-soak” manner, wherein the substrate moves through various process regions of the system in a step-wise manner.

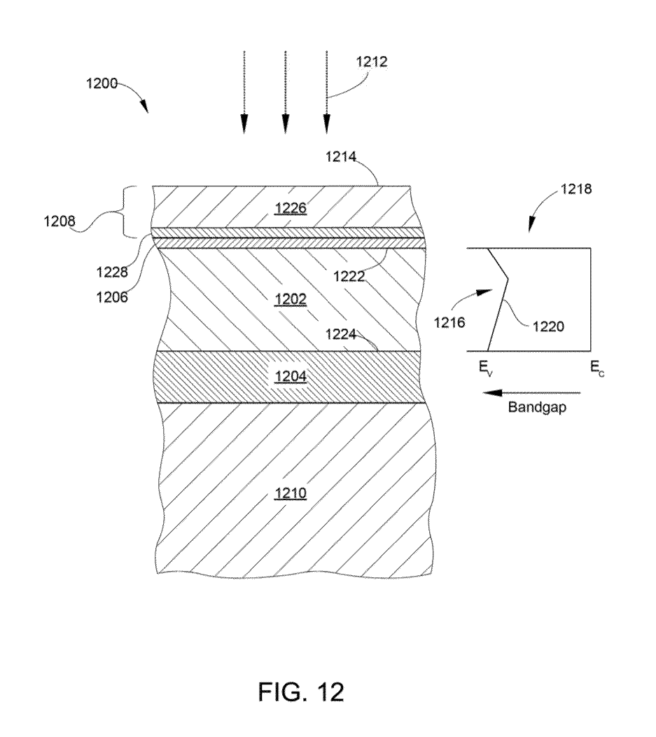

FIG. 12 is a schematic cross-sectional view of a TFPV device 1200 with a CIGS absorber layer 1202, configured according to some embodiments of the present invention. TFPV device 1200 includes a back contact layer 1204, CIGS absorber layer 1202, a buffer layer 1206, and a TCO stack 1208, arranged as shown on a substrate 1210 to form a TFPV device stack. Light 1212 is incident on a front surface 1214 of TFPV device 1200, passes through TCO stack 1208 and buffer layer 1206, and is absorbed by CIGS absorber layer 1202 and converted to electrical energy.

Substrate 1210 may be a rigid or flexible substrate. Examples of rigid substrates suitable for use as substrate 1210 include float glass, low-iron glass, borosilicate glass, specialty glass for high temperature processing, stainless steel, carbon steel, aluminum, copper, titanium, molybdenum, plastics, etc. Examples of flexible substrates suitable for use as substrate 1210 include polyimide, flexible glass, cladded metal foils, etc.

Back contact layer 1204 serves as the primary current conductor layer of TFPV device 1200 and is also configured to reflect most unabsorbed light back into CIGS absorber layer 1202. In some embodiments, back contact layer 1204 comprises a molybdenum (Mo) layer that has a thickness between 0.3 microns and 1.0 microns. In addition to high reflectivity, it is desirable for back contact layer 1204 to have relatively high electrical conductivity, good ohmic contact to CIGS absorber layer 1202, ease of bonding to tabs for external connectivity, ease of scribing or other removal, good thermo-mechanical stability, and chemical resistance during subsequent processing, among properties. Back contact layer 1204 may be formed by any number of deposition technologies, including physical vapor deposition PVD (sputtering), evaporation, CVD, ALD, plating, etc.

CIGS absorber layer 1202 is a p-type absorber layer having a thickness of between 1.0 micron and 4.0 microns and includes a CIGS material formed according to some embodiments of the invention. Specifically, CIGS absorber layer 1202 has a double-graded bandgap profile 1216, which is illustrated schematically in bandgap profile diagram 1218 shown in FIG. 12. For clarity, bandgap profile diagram 1218 is disposed adjacent to and aligned with CIGS absorber layer 1202 to better illustrate the change in the bandgap value 1220 of CIGS absorber layer 1202 with respect to a light-receiving surface 1222 and a back contact surface 1224 of CIGS absorber layer 1202. Bandgap value 1220 represents the energy difference between the top of the valence band and the bottom of the conduction band in CIGS absorber layer 1202. As shown in bandgap profile diagram 1218, bandgap profile 1216 is “double-graded,” i.e., the bandgap value 1220 increases toward light-receiving surface 1222 and also toward back contact surface 1224, with a bandgap minimum located in a center region of the CIGS absorber layer 1202. Because bandgap value 1220 increases at light-receiving surface 1222, the generation of carriers near light-receiving surface 1222 is discouraged, thereby advantageously reducing recombination. Because bandgap value 1220 increases at back contact surface 1224, a back surface field is created, which reduces recombination at back contact surface 1224 and enhances carrier collection. Bandgap profile 1216 is double-graded since the concentration of gallium in CIGS absorber layer 1202 is also double-graded, with an increased concentration of gallium at light-receiving surface 1222 and also at back contact surface 1224.

According to some embodiments, CIGS absorber layer 1202 is formed on back contact layer 1204 in a two-step process that does not include sulfur incorporation. It is noted that embodiments of the invention produce a double-graded concentration of gallium in CIGS absorber layer 1202 so that CIGS absorber layer 1202 has a double-graded bandgap profile 1216, as illustrated in bandgap profile diagram 1218. First, a precursor film that includes copper, indium, and gallium is deposited on back contact layer 1204, with sputtering, evaporation, electroplating, solution-based synthesis, or other metal deposition processes known in the art. For example, a co-sputtering process may be performed using binary copper-gallium and indium sputter targets. The copper-indium-gallium precursor film may comprise multiple layers or a single layer, and may be a dense or porous film. Subsequent to deposition of the copper-indium-gallium precursor film, one of several possible embodiments of the invention is used to form CIGS absorber layer 1202 with a double-graded concentration of gallium, so that CIGS absorber layer 1202 has double-graded bandgap profile 1216.

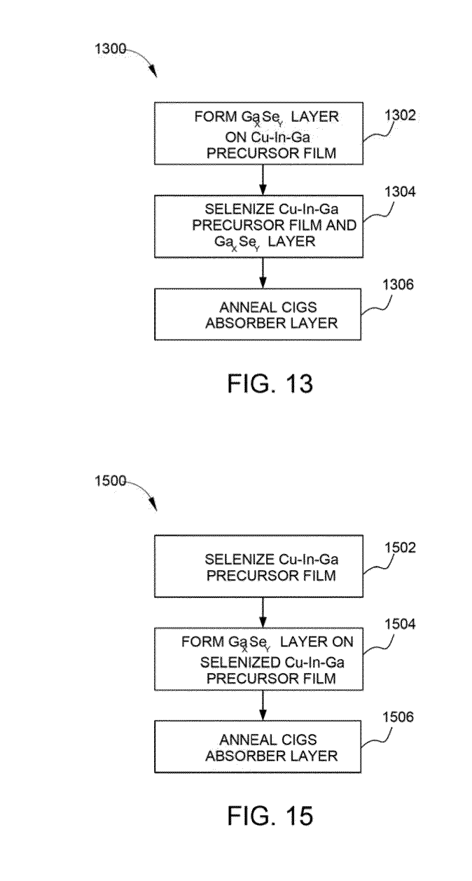

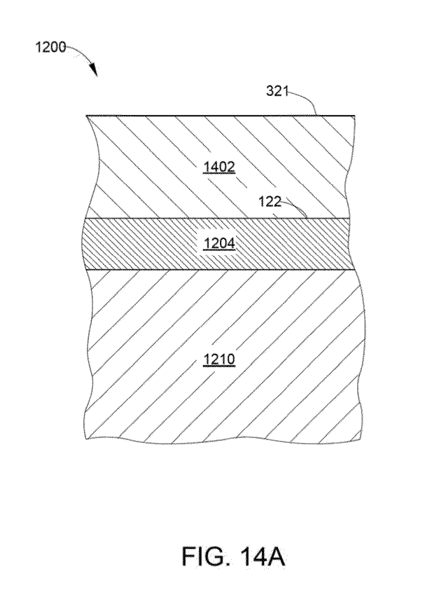

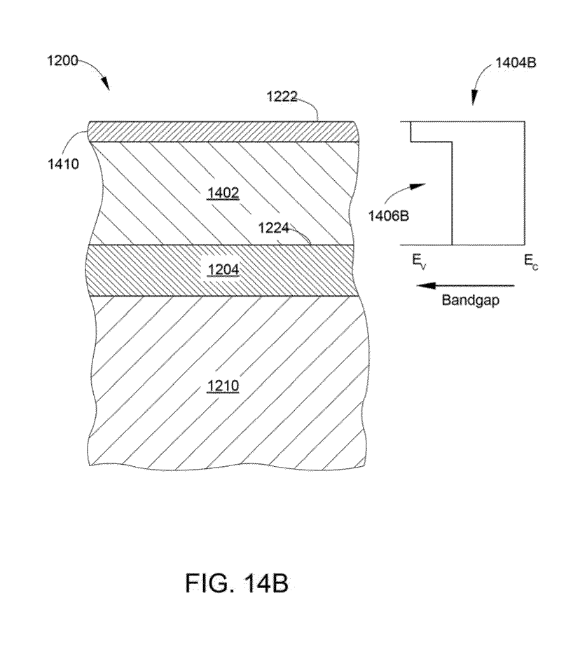

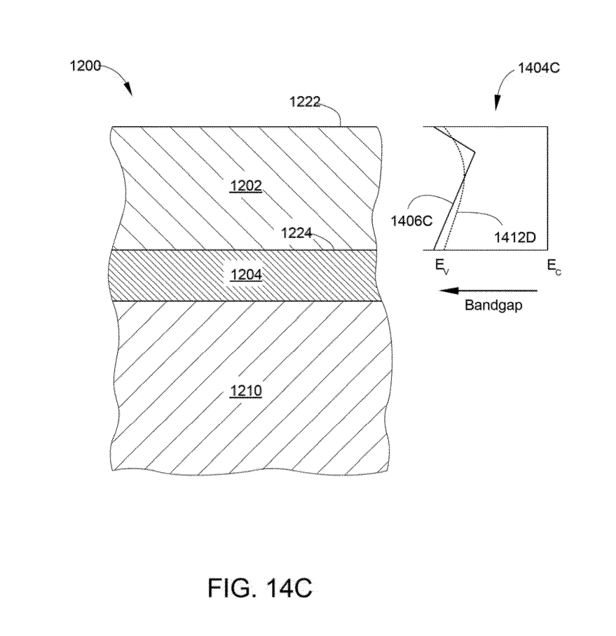

In some embodiments, a GaₓSe_{y} layer is formed on the copper-indium-gallium precursor film using trimethyl gallium (TMGa) gas and a selenium (Se) containing gas in an initial, low-temperature selenization process, in which the selenium-containing gas used in the selenization process does not react with the copper-indium-gallium precursor film. A subsequent high-temperature selenization process forms the typical gallium-rich region at back contact surface 1224 of CIGS absorber layer 1202 while simultaneously converting the deposited GaₓSe_{y} layer to a gallium-rich region at light-receiving surface 1222 of CIGS absorber layer 1202. The embodiment is described in greater detail below in conjunction with FIG. 13 and FIGS. 14A-C.

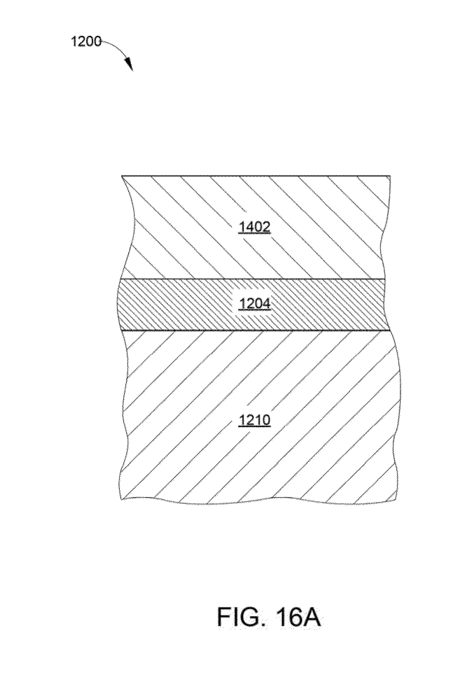

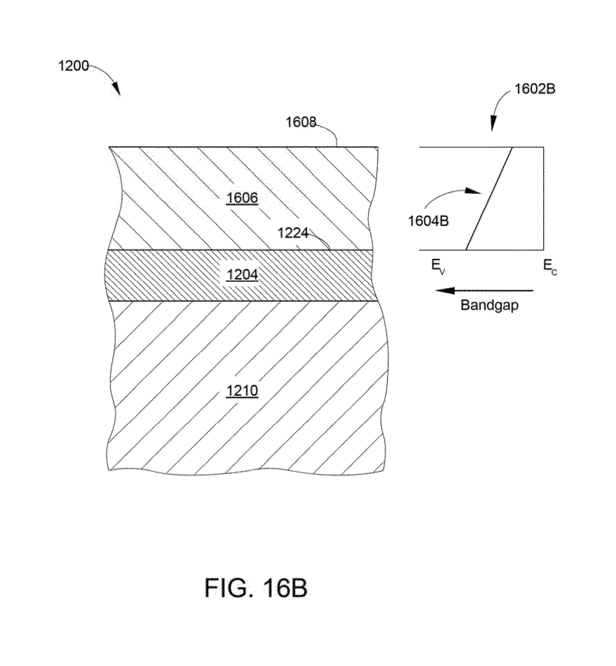

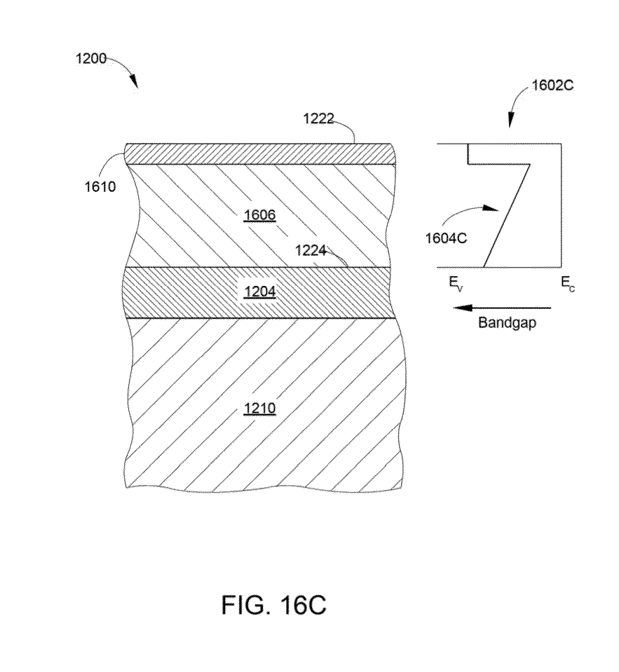

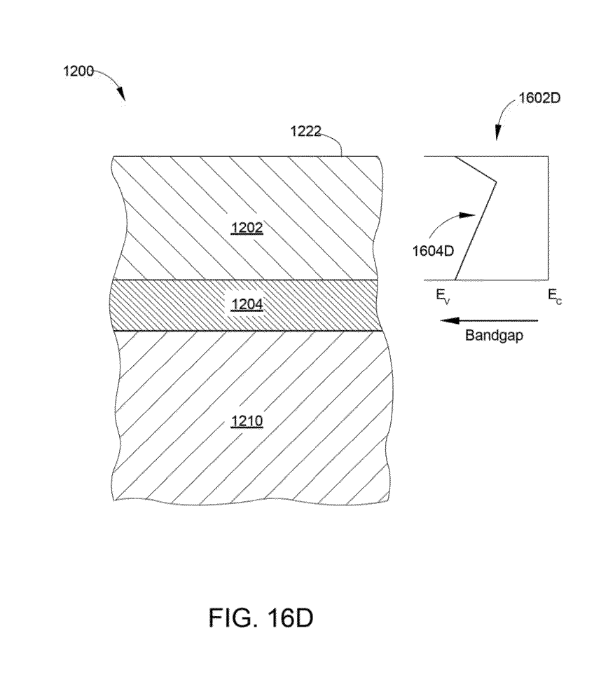

In some embodiments, the copper-indium-gallium precursor film first undergoes a conventional selenization process to form a CIGS absorber layer that has the typical gallium-rich region at back contact surface 1224 and therefore has a single-graded bandgap profile. Then, using TMGa and a selenium-containing gas, a GaₓSe_{y} layer is formed on light-receiving surface 1222 of the single-graded CIGS absorber layer, and a subsequent anneal process converts the deposited GaₓSe_{y} to a gallium-rich region at the front surface of the absorber. The embodiment is described in greater detail below in conjunction with FIG. 15 and FIGS. 16A-D.

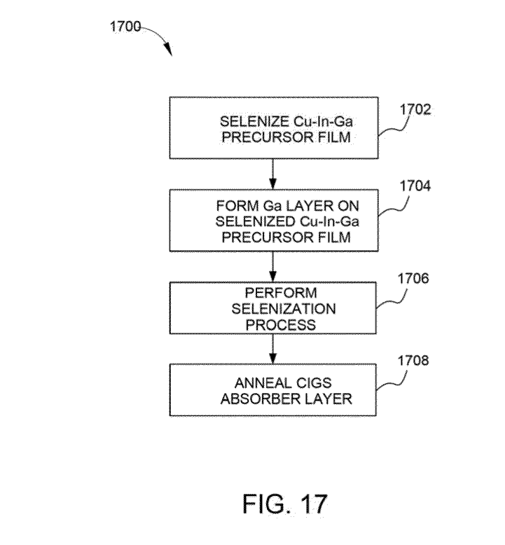

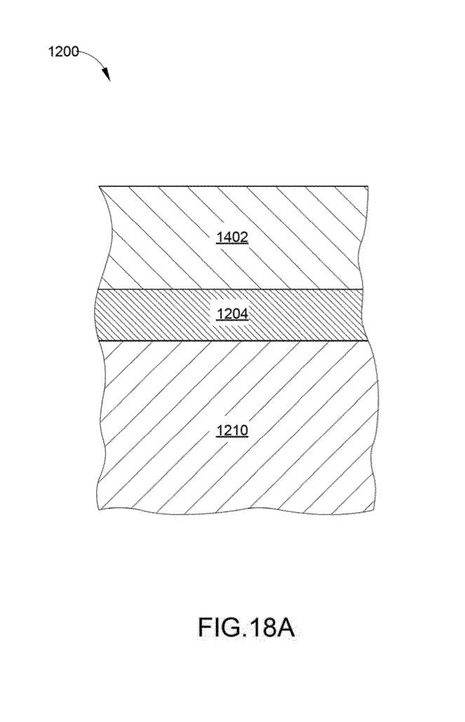

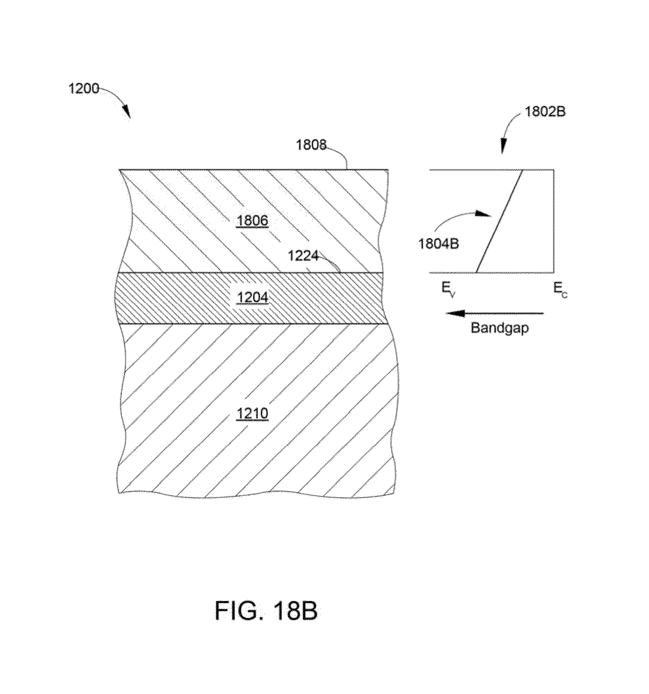

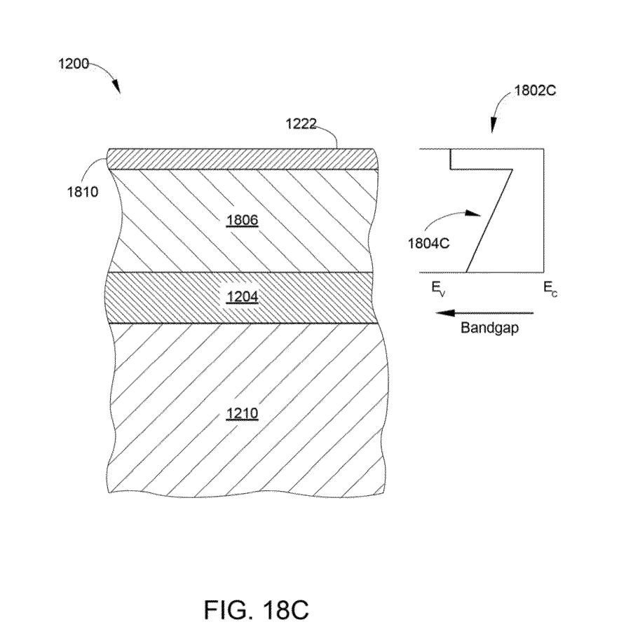

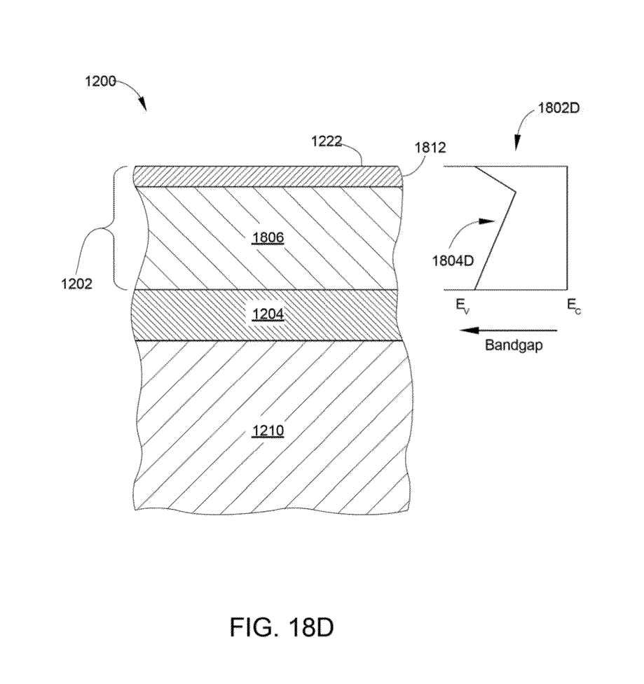

In some embodiments, the copper-indium-gallium precursor film first undergoes a conventional partial or complete selenization process to form a CIGS absorber layer that has the typical gallium-rich region at back contact surface 1224 and a single-graded bandgap profile. Then, thermal pyrolysis of TMGa is used to deposit a gallium layer on light-receiving surface 1222 of the single-graded CIGS absorber layer, and a subsequent selenization process forms a GaₓSe_{y} layer from the deposited gallium. Depending on the temperature of the selenization process, an anneal process may be used in a final step to convert the GaₓSe_{y} layer to a gallium-rich region at light-receiving surface 1222 of CIGS absorber layer 1202. The embodiment is described in greater detail below in conjunction with FIG. 17 and FIGS. 18A-E.

Buffer layer 1206 of TFPV device 1200 is an n-type buffer layer deposited on CIGS absorber layer 1202. In some embodiments, buffer layer 1206 comprises a cadmium sulfide (CdS) layer that has a thickness between 30 nm and 100 nm. Other n-type buffer layer materials suitable for use in buffer layer 1206 include ZnS, In₂S₃, In₂(S, Se)₃, CdZnS, ZnO, Zn(O, S), (Zn, Mg)O, etc. Buffer layer 1206 may be deposited using chemical bath deposition (CBD), chemical surface deposition (CSD), PVD, printing, plating, ALD, ion-layer-gas-reaction (ILGAR), or evaporation.

TCO stack 1208 serves as part of the front contact structure of TFPV device 1200 and is formed from transparent conductive metal oxide materials. TCO stack 1208 collects charge across the face of TFPV device 1200 and conducts the charge to tabs used to connect TFPV device 1200 to external loads. TCO stack 1208 includes a low resistivity top TCO layer 1226 and an optional intrinsic zinc oxide (iZnO) layer 1228. Optional intrinsic zinc oxide layer 1228 is a high resistivity material that has been found to reduce sensitivity of TFPV device to lateral non-uniformities caused by differences in composition or defect concentration in the absorber and/or buffer layers. Optional intrinsic zinc oxide layer 1228 is formed on CIGS absorber layer 1202 and is generally between 40 to 60 nm in thickness, but in some embodiments is up to about 150 nm in thickness. Optional intrinsic zinc oxide layer 1228 is typically formed using deposition processes well-known in the art, including reactive PVD, CVD, plating, or printing. Low resistivity top TCO layer 1226 is formed on optional intrinsic zinc oxide layer 1228, and typically has a thickness between 100 nm and 1 micron. Suitable materials for low resistivity top TCO layer 1226 include aluminum-doped zinc oxide (Al:ZnO), indium tin oxide (InSnO or ITO), indium zinc oxide (InZnO), boron-doped zinc oxide (B:ZnO), gallium-doped zinc oxide (Ga:ZnO), fluorine-doped zinc-oxide (F:ZnO), fluorine-doped tin oxide (F:SnO₂), etc. Suitable processes for forming low resistivity top TCO layer 1226 include reactive PVD, CVD, printing or wet-coating from nano-wires or carbon nanotubes, and the like.

FIG. 13 sets forth a flowchart of method steps in a process sequence 1300 for forming CIGS absorber layer 1202, according to embodiments of the invention. FIGS. 14A-D sequentially illustrate cross-sectional views of TFPV device 1200 during the execution of process sequence 1300, according to embodiments of the invention. Although the method steps are described in conjunction with TFPV device 1200, persons skilled in the art will understand that formation of other TFPV devices using process sequence 1300 is within the scope of the invention. Prior to the first step of method 1300, back contact layer 1204 is deposited on substrate 1210, and a copper-indium-gallium precursor film 1402 is formed on back contact layer 1204 (shown in FIG. 14A). In an exemplary embodiment, copper-indium-gallium precursor film 1402 has a thickness of 200 nm to 1000 nm and a composition range of copper to indium and gallium (i.e. Cu/(In +Ga)) of 0.7 to 0.95 and gallium to gallium and indium of (i.e. Ga/(In +Ga)) of 0.1 to 0.4.

As shown in FIG. 13, method 1300 begins at step 1302, in which the reaction of TMGa vapor with a selenium-containing gas is used to form a GaₓSe_{y} layer 1410 on copper-indium-gallium precursor film 1402, (illustrated in FIG. 14B). In addition, the reaction between the TMGa vapor and the selenium-containing gas is performed at a relatively low temperature, so that the selenium-containing gas used in the selenization process does not react with copper-indium-gallium precursor film 1402. In such a selenization process, the temperature of substrate 1210 is maintained below the reaction threshold temperature for the selenization of copper-indium-gallium precursor film 1402, so that GaₓSe_{y} layer 1410 is formed on copper-indium-gallium precursor film 1402 as shown in FIG. 14B. Bandgap profile diagram 1404B in FIG. 14B illustrates that bandgap profile 1406B of copper-indium-gallium precursor film 1402 remains substantially constant, since little or no gallium diffuses into copper-indium-gallium precursor film 1402 during step 1302. However, the high concentration of gallium in GaₓSe_{y} layer 1410 results in a higher bandgap at light-receiving surface 1222.

Various selenium-containing gases may be used in step 1302 to form GaₓSe_{y} layer 1410, including hydrogen selenide (H₂Se), selenium vapor (Se), and/or diethylselenide (DESe). In some embodiments, step 1302 takes place in either a batch furnace or an in-line furnace at a deposition temperature between 20° C. and 350° C., and hydrogen selenide is used as the selenium-containing gas. In such an embodiment, GaₓSe_{y} layer 1410 is deposited with a thickness of 10 nm to 100 nm using the reaction described in Equation 1:

$$3 {( C {H}_{3} )}_{3} {Ga}_{( g )} + 4 {H}_{2} {Se}_{( g )} + \frac{1}{2} {H}_{2 ( g )} -> {Ga}_{2} {Se}_{3 ( s )} + Ga {Se}_{( s )} + 9 C {H}_{4 ( g )} \qquad ( 1 )$$

In step 1304, selenization of copper-indium-gallium precursor film 1402 and GaₓSe_{y} layer 1410 is performed by reaction with a selenium-containing gas that comprises hydrogen selenide, selenium vapor, diethylselenide, and/or a combination thereof. The selenization process of step 1304 forms CIGS absorber layer 1202 from copper-indium-gallium precursor film 1402 and GaₓSe_{y} layer 1410, as shown in FIG. 14C. The reaction with the selenium-containing gas takes place at an elevated temperature (e.g., between 400° C. and 550° C.) so that gallium present in copper-indium-gallium precursor film 1402 reacts with the selenium-containing gas to form a CIGS absorber layer that is gallium-rich at back contact surface 1224. However, at such reaction temperatures, gallium contained in GaₓSe_{y} layer 1410 has limited mobility due to the strong Ga—Se bond, and remains concentrated near light-receiving surface 1222 of CIGS absorber layer 1202. Consequently, upon completion of step 1304, CIGS absorber layer 1202 has a double-graded bandgap profile 1406C, as illustrated in bandgap profile diagram 1404C of FIG. 14C.

In some embodiments, the selenium-containing gas comprises hydrogen selenide and the reaction temperature is between 400° C. and 550° C. In some embodiments, the selenium-containing gas comprises selenium vapor and the reaction temperature is between 400° C. and 600° C. It is noted that the processes described for step 1304 may be performed in the same batch furnace or in-line furnace that performs the processes of step 1302. Consequently, implementation of method 1300 is substantially more economical and less complex than processes in which multiple processing chambers are required for the formation of CIGS absorber layer 1202.

In optional step 1306, double-graded bandgap profile 1406C illustrated in FIG. 14C is tuned or optimized in a final anneal process. The anneal process of step 1306 can adjust the Ga distribution in CIGS absorber layer 1202, thereby altering the double-graded bandgap profile 1406C. For example, in some embodiments, the anneal process of step 1306 adjusts double-graded bandgap profile 1406C to a double-graded bandgap profile 1406D. In some embodiments, the anneal process of step 1306 is performed at a temperature greater than or equal to 500° C. It is noted that in some embodiments, depending on the reaction temperature and duration of the selenization process of step 1304, step 1306 may not be necessary. Specifically, in some embodiments, double-graded bandgap profile 1406C may be adjusted to double-graded bandgap profile 1406D during the selenization process of step 1304, i.e., when the selenization process of step 1304 takes place at a sufficiently high temperature and for a sufficiently long duration.

FIG. 15 sets forth a flowchart of method steps in a process sequence 1500 for forming CIGS absorber layer 1202, according to embodiments of the invention. FIGS. 16A-D sequentially illustrate cross-sectional views of TFPV device 1200 during the execution of process sequence 1500, according to embodiments of the invention. Although the method steps are described in conjunction with TFPV device 1200, persons skilled in the art will understand that formation of other TFPV devices using process sequence 1500 is within the scope of the invention. Prior to the first step of method 1500, back contact layer 1204 and copper-indium-gallium precursor film 1402 are deposited on substrate 1210 as described above in method 1300.

As shown in FIG. 15, method 1500 begins at step 1502, in which a selenization process known in the art is performed on copper-indium-gallium precursor film 1402 to form a CIGS layer 1606, as shown in FIG. 16B. Due to gallium's slower reaction kinetics with selenium compared to indium, gallium accumulates towards back contact surface 1224 of CIGS layer 1606 during the selenization process, so that CIGS layer 1606 has a single-graded bandgap profile that increases from front surface 1608 of CIGS layer 1606 to back contact surface 1224. Bandgap profile diagram 1602B in FIG. 16B illustrates the single-graded bandgap profile 1604B of CIGS layer 1606. Selenization processes suitable for use in step 1502 may be performed in a batch furnace or in-line furnace, are typically carried out in a temperature range of approximately 400° C. to 500° C., and generally use hydrogen selenide and/or selenium vapor.

In step 1504, the reaction of TMGa vapor with a selenium-containing gas is used to form a GaₓSe_{y} layer 1610 on CIGS layer 1606, illustrated in FIG. 16C. The process of forming GaₓSe_{y} layer 1610 on CIGS layer 1606 is similar to the process of forming GaₓSe_{y} layer 1410 on copper-indium-gallium precursor film 1402 in step 1302 of method 1300, but differs in one respect. Specifically, the reaction described in Equation 1 can be performed in step 1504 at a higher temperature than in step 1302 of method 1300, e.g., up to 550° C., since CIGS layer 1606 is already chalcogenized in step 1502. As illustrated by bandgap profile diagram 1602C, bandgap profile 1604C of CIGS layer 1606 has a single grade that increases toward back contact surface 1224, while the high concentration of gallium in GaₓSe_{y} layer 1610 results in a correspondingly higher bandgap at light-receiving surface 1222. It is noted that the processes described for step 1504 may be performed in the same batch furnace or in-line furnace that performs the processes of step 1502.

In step 1506, an anneal process is performed on CIGS layer 1606 and GaₓSe_{y} layer 1610 to form CIGS absorber layer 1202, as illustrated in FIG. 16D. The anneal process of step 1506 converts GaₓSe_{y} layer 1610 into a gallium-rich CIGS region at light-receiving surface 1222, so that the bandgap of CIGS absorber layer 1202 increases at light-receiving surface 1222. Thus, in step 1506, CIGS absorber layer 1202 is formed with a double-graded bandgap profile, as illustrated by bandgap profile 1604D in bandgap profile diagram 1602D. The duration and temperature at which the anneal process of step 1506 takes place may be selected to adjust bandgap profile 1604D as desired. In some embodiments, the anneal process of step 1506 is performed at a temperature between 500° C. and 600° C. It is noted that the anneal process of step 1506 may be performed in the same batch furnace or in-line furnace that performs the processes of steps 1502 and 1504.

FIG. 17 sets forth a flowchart of method steps in a process sequence 1700 for forming CIGS absorber layer 1202, according to embodiments of the invention. FIGS. 18A-D sequentially illustrate cross-sectional views of TFPV device 1200 during the execution of process sequence 1700, according to embodiments of the invention. Although the method steps are described in conjunction with TFPV device 1200, persons skilled in the art will understand that formation of other TFPV devices using process sequence 1700 is within the scope of the invention. Prior to the first step of method 1700, back contact layer 1204 and copper-indium-gallium precursor film 1402 are deposited on substrate 1210 as described above in method 1300.

As shown in FIG. 17, method 1700 begins at step 1702, in which a selenization process known in the art is performed on copper-indium-gallium precursor film 1402 to form a CIGS layer 1806, as shown in FIG. 18B. Step 1702 is substantially similar to step 1502 in method 1500, so that CIGS layer 1806 has a single-graded bandgap profile that increases from front surface 1808 of CIGS layer 1806 to back contact surface 1224. Bandgap profile diagram 1802B in FIG. 18B illustrates the single-graded bandgap profile 1804B of CIGS layer 1806.

In step 1704, a gallium layer 1810 is formed on CIGS layer 1806, illustrated in FIG. 18C. For visualization purposes, the Gallium layer has been arbitrarily assigned a higher bandgap value. Gallium layer 1810 is formed by exposing CIGS layer 1806 to TMGa vapor at a temperature between 400° C. and 550° C. Thermal pyrolysis of the TMGa vapor results in the deposition of gallium layer 1810. It is noted that the processes described for step 1704 may be performed in the same batch furnace or in-line furnace that performs the processes of step 1702. Bandgap profile diagram 1802C (FIG. 18C) illustrates the single-graded bandgap profile 1804C of CIGS layer 1806 and the high bandgap value at light-receiving surface 1222 associated with gallium layer 1810.

It is noted that the formation of gallium layer 1810 in step 1704 results from the thermal decomposition of TMGa on the exposed surface of copper-indium-gallium precursor film 1402. This is in contrast to the formation of GaₓSe_{y} layer 1610 on copper-indium-gallium precursor film 1402, in step 1504 of method 1500, which is a gas-phase reaction that can potentially create unwanted particles the reaction chamber.

In step 1706, a selenization process is performed with a selenium-containing gas. Selenization processes suitable for use in step 1706 may be performed in a batch furnace or in-line furnace, are typically carried out in a temperature range of approximately 400° C. to 550° C., and generally use hydrogen selenide and/or selenium vapor. The selenization process of step 1706 converts gallium layer 1810 to a GaₓSe_{y} layer 1812, illustrated in FIG. 18D, and produces the desired double-graded bandgap profile, as illustrated by bandgap profile 1804D in bandgap profile diagram 1802D.

In optional step 1708, an anneal process is performed on CIGS absorber layer 1202. The anneal process of step 1708 may be used to further optimize or adjust the bandgap profile of CIGS absorber layer 1202. In some embodiments, the anneal process in step 1708 is performed at a temperature between 500° C. and 600° C.

It is noted that the processes described for steps 1702-1708 may all be performed in the same batch furnace or in-line furnace. Consequently, implementation of method 1700 is substantially more economical and less complex than processes in which multiple processing chambers are required for the formation of CIGS absorber layer 1202. It is further noted that embodiments of the invention may be performed using any technically feasible deposition techniques known in the art. For example, TFPV device 1200 may be formed using single substrate processing equipment, multiple substrate batch-processing equipment, in-line processing, single chamber processing, roll-to-roll processing, and the like. In-line processing may include continuous processing of substrates while moving through an in-line furnace, or the performance of different processes on each substrate in multiple discrete reaction chambers. Such chambers may be isolated mechanically, by gas curtains, etc.

Absorber materials formed from Group IB-IIB-IVA-VIA elements are alternatives to the CIGS materials as discussed previously. An illustrative example comprises Cu—Zn—Sn—(S, Se) (i.e. CZTS). Examples of the bandgap values for these materials range from 0.95 eV for Cu₂(Cd, Sn)(S, Se)₄ to 1.6 eV for Cu₂(Zn, Ge)(S, Se)₄. These materials have the added advantage in that they are formed from elements that are abundant and less expensive than the In and Ga portions of the CIGS materials. Similar to the CIGS materials, a double grading in the bandgap of these materials can be induced through the compositional grading of several of the components. Advantageously, the materials are Group IB poor (i.e. IB/(IIB+IVA)<1.0) and Group IIB rich (i.e. IIB/(IIB+IVA)>0.5). Specific examples of composition grading that can be used to alter the bandgap comprise S/(S+Se) and Ge/(Sn+Ge). More generically, examples of composition grading that can be used to alter the bandgap comprise Ag/(Cu+Ag), Te/VIA, S/VIA, Se/VIA, 0/VIA, IIB/IVA, Zn/IIB, Cd/IIB, Hg/IIB, Ge/IVA, and Sn/IVA.

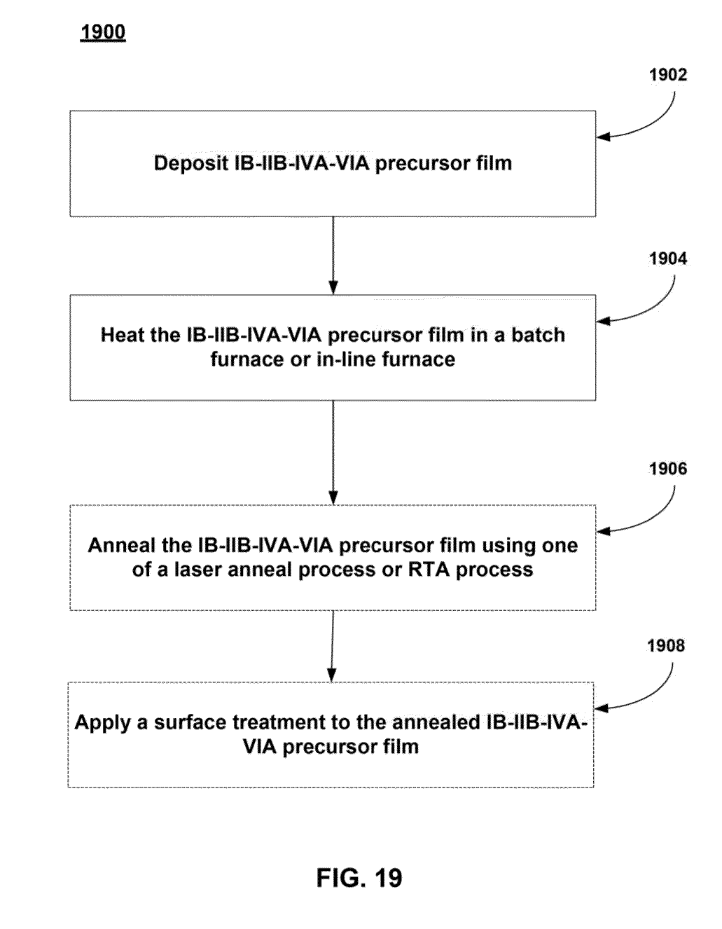

In some embodiments, Group IB-IIB-IVA-VIA (e.g. CZTS) absorber materials having a double graded bandgap can be formed using a 2-step process wherein Zn, Ge, or Ag is used to promote the increase of the bandgap at the front and back surfaces of the absorber as illustrated in FIG. 19. In step 1902, a Group IB-IIB-IVA-VIA precursor film is formed on a molybdenum/substrate structure. As discussed earlier, additional layers that act as diffusion barriers and/or adhesion layers may be formed between the molybdenum back contact material and the substrate. Typically, the substrate is glass, but may be other materials such as polymers, metal foils, etc.

The Group IB-IIB-IVA-VIA precursor film is formed at a thickness between 300 nm and 3000 nm, preferably between 1500 nm and 2500 nm. If the substrate structure is heavily textured (non-planar), then the thickness may range between 500 nm and 1500 nm. The Group IB-IIB-IVA-VIA precursor film may be formed as a single layer or may include a number of sub-layers (e.g. a nanolaminate). The Group IB-IIB-IVA-VIA precursor film may be formed with a uniform composition throughout the thickness, or a compositional gradient of one or more of the bandgap tuning elements (e.g. Zn, Ge, Ag, or others) is formed by varying their composition during the deposition. The Group IB-IIB-IVA-VIA precursor film may be formed with one of an amorphous structure, a nano-crystalline structure, a micro-crystalline structure, or a poly-crystalline structure.

The Group IB-IIB-IVA-VIA precursor film may be formed by any of the techniques discussed previously such as batch or in-line (co)evaporation, batch or in-line PVD (sputtering), batch or in-line ALD, CVD, Plasma enhanced CVD (PECVD), Plasma enhanced ALD (PEALD), atmospheric pressure CVD (APCVD), ultra-fast atmospheric ALD, plating, printing or spraying of inks, screen printing, inkjet printing, slot die coating, gravure printing, wet chemical depositions, etc.

As discussed previously, the process parameters used for depositing the Group IB-IIB-IVA-VIA precursor film can be varied during the investigation of the materials. Using PVD (sputtering) as an example, the targets used for the deposition may include metal targets, alloy targets, chalcogenide targets, or a mixture thereof. The substrate temperature during the deposition may be varied between 100 and 400 C, preferably between 25 C and 200 C, and more preferably between 25 C and 100 C. The pressure within the process chamber during the deposition may be varied between 1 mTorr and 30 mTorr, preferably between 2 mTorr and 15 mTorr, and more preferably between 2 mTorr and 10 mTorr. The atmosphere within the process chamber during the deposition may be non-reactive (e.g. only argon) or reactive (e.g. argon with a mixture of chalcogen containing sources). Examples of typical chalcogen containing sources are vapors, e.g., S, Se, Te, or gases including H₂S, H₂Se, H₂Te, and others.

Advantageously, the Group IB-IIB-IVA-VIA precursor film has a composition range of IB/(IIB+IVA)=0.7-1.0 (e.g. Cu-poor) and IIB/(IIB+IVA)>0.45. In step 1904, the Group IB-IIB-IVA-VIA precursor film is exposed to a chalcogenization process to form a Group IB-IIB-IVA-VIA absorber material by heating the film in the presence of a chalcogen. The heating may be performed in a batch furnace or an in-line furnace. The temperature of the heating may range between 300 C and 700 C, preferably between 350 C and 650 C, and more preferably between 400 C and 600 C. The chalcogen may include gases such as H₂S, H₂Se, H₂Te, S-vapor, Se-vapor, Te-vapor, or other gases such as volatile tin compounds (e.g. a Sn—S compound, a Sn—Se compound, a Sn—Te compound, etc.).

In optional step 1906, an anneal process is performed on the Group IB-IIB-IVA-VIA absorber layer. The anneal process of step 1906 may be used to further optimize or adjust the bandgap profile of the Group IB-IIB-IVA-VIA absorber layer. In some embodiments, the anneal process in step 1906 is a short, directed energy anneal process such as a laser annealing process or a rapid thermal anneal (RTA) process. Advantageously, the optional anneal process in step 1906 is performed in an inert atmosphere at around atmospheric pressure. Details of an example laser annealing process are described in U.S. patent application Ser. No. 13/204,827 (now U.S. Pat. No. 8,551,802), filed on Aug. 8, 2011, which is herein incorporated by reference for all purposes.

In optional step 1908, a surface treatment may be applied to the annealed surface. The surface treatment may be a wet process or a dry process. The purpose of the surface treatment is to remove unwanted impurity phases and/or change the surface composition of the film.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a semiconductor material on a substrate comprising:
depositing a layer above a surface of the substrate, wherein the layer comprises at least one element from each of Group IB, Group IIB, Group IVA, and Group VIA of the periodic table;
and
heating the layer in the presence of a chalcogen at a temperature between 300 C and 700 C.

2. The method of claim 1 wherein a composition of the Group IB element in the layer as given by IB/(IIB+IVA) is between 0.70 and 1.0.

3. The method of claim 1 wherein a composition of the Group IIB element in the layer as given by IIB/(IIB+IVA) is greater than 0.45.

4. The method of claim 1 further comprising annealing the substrate after the heating step.

5. The method of claim 4 wherein the annealing the substrate after the heating step comprises one of a laser annealing process or a rapid thermal annealing process.

6. The method of claim 5 further comprising applying a surface treatment to the substrate after the annealing step.

7. The method of claim 1 wherein the layer comprises copper, zinc, tin, and at least one of sulfur or selenium.

8. The method of claim 7 wherein the layer further comprises at least one of silver or germanium.

9. The method of claim 1 wherein the layer is deposited using a sputtering process.

10. The method of claim 9 wherein at least one target used in the sputtering process comprises a metal target, a metal alloy target, or a chalcogenide target.

11. The method of claim 9 wherein a temperature of the substrate during the depositing is between 10 C and 400 C.

12. The method of claim 11 wherein the temperature of the substrate during the depositing is between 25 C and 100 C.

13. The method of claim 9 wherein a pressure within a process chamber during the depositing is between 1 mTorr and 30 mTorr.

14. The method of claim 13 wherein the pressure within a process chamber during the depositing is between 2 mTorr and 10 mTorr.

15. The method of claim 9 wherein an atmosphere within a process chamber during the depositing comprises a chalcogen containing source.

16. The method of claim 15 wherein the atmosphere within a process chamber during the depositing comprises at least one of H₂S, H₂Se, H₂Te, S-vapor, Se-vapor, or Te-vapor.

17. The method of claim 1 wherein the chalcogen comprises at least one of H₂S, H₂Se, or H₂Te.

18. The method of claim 1 wherein the chalcogen comprises at least one of a Sn—S compound, a Sn—Se compound, or a Sn—Te compound.

19. The method of claim 1 wherein the layer comprises copper, zinc, tin, and at least one of sulfur or selenium, wherein the layer is heated to a temperature between 400 C and 600 C in the presence of at least one of H₂S, H₂Se, H₂Te, S-vapor, Se-vapor, or Te-vapor.

20. The method of claim 19 wherein the layer further comprises at least one of silver or germanium.
